(19) United States
(12) Patent Application Publication
(10) Pub. No.: US 2010/0271927 A1
(43) Pub. Date: Oct. 28, 2010

(54) OPTICAL PICKUP, OPTICAL DISC APPARATUS, OPTICAL PICKUP MANUFACTURING METHOD, AND OPTICAL PICKUP CONTROL METHOD

(75) Inventor: Masamichi Furuichi, Kanagawa (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 12/763,369

(22) Filed: Apr. 20, 2010

(30) Foreign Application Priority Data
Apr. 27, 2009 (JP) 2009-108248

(51) Int. Cl. G11B 7/00; H05K 13/00

(52) U.S. Cl. 369/112.24; 29/592.1; G9B/7

(57) ABSTRACT

An optical pickup includes: first and second objective lenses focusing light beams of different wavelengths on first and second optical discs having different thickness protection layers; a coma aberration generating unit generating coma aberration in the light beams; a collimating lens between a light source and the first objective lens; and a collimating lens driving unit. The protection layer thickness of the plastic first optical disc is smaller than that of the second optical disc. The first objective lens satisfies a lens tilt coma aberration sensitivity of 0 to 0.3[λrms/°]. An optical axis of the light beam approximately coincides with an optical axis of the first objective lens. The optical pickup is inclined to the optical disc so that initial coma aberration with respect to the first optical disc is optimally corrected. The coma aberration generating unit is used for obtaining optimal reproducing environment when reproducing the second optical disc.

### BACKGROUND OF THE INVENTION

1. Field of the Invention

The present invention relates to an optical pickup for performing recording and/or reproducing of information with respect to an optical recording medium such as an optical disc, an optical disc apparatus using the optical pickup, an optical pickup manufacturing method, and an optical pickup control method.

2. Description of the Related Art

In the related art, there is a CD (Compact Disc) which uses a light beam having a wavelength of about 785 nm as a recording medium of an information signal. Further, there is an optical disc such as a DVD (Digital Versatile Disc) which uses a light beam having a wavelength of about 660 nm. The DVD realizes high density recording compared with the CD. Furthermore, there is an optical disc capable of high density recording (hereinafter, referred to as a high density recording optical disc) which performs recording and/or reproducing of signals using a light beam having a wavelength of about 405 nm emitted from a blue purple semiconductor laser, which realizes higher density recording compared with a DVD. As such a high density recording optical disc, for example, there is proposed an optical disc such as BD (Blu-ray Disc, which is a registered trademark) which has a thin protection layer (covering layer) for protecting a recording layer on which a signal is recorded.

As an objective lens which is used in an optical pickup for recording an information signal onto the optical disc such as BD or reproducing the information signal recorded in the optical disc, an objective lens made of plastic has been studied, considering that the plastic objective lens is advantageous in productivity and light weight compared with an objective lens made of glass.

The plastic objective lens has a material characteristic such that its refractive index is significantly changed due to heat, and thus, may generate significant unnecessary aberrations according to usage environments thereof. In particular, in the plastic objective lens, change in spherical aberration due to temperature changes is remarkable compared with the glass objective lens in the related art, which results in deterioration of recording characteristics.

Thus, the optical pickup using the plastic objective lens typically employs a method that a collimating lens is moved in an optical axis direction to generate magnification ratio spherical aberration, to thereby correct spherical aberration generated due to the temperature changes.

However, in the case where the spherical aberration is corrected by driving the collimating lens in this way, there is a problem that sensitivity of coma aberration due to lens tilting (hereinafter, referred to as lens tilt coma aberration sensitivity) is significantly changed as a side effect due to the magnification ratio change.

On the other hand, the optical pickup in the related art employs a method that coma aberration generated due to the objective lens or optical components other than the objective lens and coma aberration generated due to the degree of assembling precision thereof is corrected by adjusting the inclination of the objective lens in a static or dynamic manner. More specifically, the inclination in a tilt direction of an actuator which holds the objective lens is statically or dynamically adjusted to perform correction of such initial coma aberration or the like.

In the temperature range of the usage environment, there is significant change in the lens tilt coma aberration sensitivity of the plastic objective lens according to its material or shape as described above, and may be under the conditions from 0° C. to about two times normal temperature. Thus, in low or high temperature environments, it is difficult to correct the coma aberration by adjusting the inclination through the actuator driving, and thus, the disc recording characteristics may be deteriorated.

Japanese Unexamined Patent Application Publication No. 2008-112575 is an example of the related art.

### SUMMARY OF THE INVENTION

It is desirable to provide an optical pickup, an optical disc apparatus, an optical pickup manufacturing method and an optical pickup control method, in which the optical pickup uses a plastic objective lens to enhance productivity and weight saving, and reduces coma aberration due to environmental temperature changes to improve recording and/or reproducing characteristics.

According to an exemplary embodiment of the present invention, there is provided an optical pickup including: a first and a second objective lenses which are configured to focus light beams having different wavelengths onto a first and a second optical discs having protection layers of different thicknesses, respectively; a coma aberration generating unit which is configured to generate coma aberration in the light beams passing through the first and/or second objective lenses; a collimating lens which is installed on a light path between a light source for emitting the light beam and the first objective lens, and is configured to convert a divergent angle of the light beam passing through the collimating lens; and a collimating lens driving unit which is configured to move the collimating lens in an optical axis direction and change an angle of the light beam entering into the first objective lens to correct spherical aberration, wherein the protection layer thickness of the first optical disc corresponding to the first objective lens is smaller than that of the second optical disc corresponding to the second objective lens, wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens, wherein the first objective lens is made of plastic and is installed so that an optical axis of the light beam, which is guided by a light guiding optical system which guides the light beam to the first objective lens, approximately coincides with an optical axis of the first objective lens, wherein the optical pickup is inclined relative to the optical disc at an angle at which initial coma aberration with respect to the first optical disc due to the first objective lens is optimally corrected, and wherein the coma aberration generating unit is not used when reproducing the first optical disc and the coma aberration generating unit is used for obtaining optimal reproducing environment when reproducing the second optical disc.

Further, according to another exemplary embodiment of the present invention, there is provided an optical disc apparatus including an optical pickup which emits a light beam onto an optical disc which is driven to rotate, so as to perform recording and/or reproducing of an information signal. Here, the optical pickup includes: a first and a second objective lenses which are configured to focus light beams having different wavelengths onto a first and a second optical discs having protection layers of different thicknesses, respectively; a coma aberration generating unit which is configured to generate coma aberration in the lights beam passing through the first and/or second objective lenses; a collimating lens which is installed on a light path between a light source for emitting the light beam and the first and second objective lenses, and is configured to convert a divergent angle of the light beams passing through the collimating lens; and a collimating lens driving unit which is configured to move the collimating lens in an optical axis direction and change angles of the light beams entering into the objective lenses to correct spherical aberration, wherein the protection layer thickness of the first optical disc corresponding to the first objective lens is smaller than that of the second optical disc corresponding to the second objective lens, wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens, wherein the first objective lens is made of plastic and is installed so that an optical axis of the light beam, which is guided by a light guiding optical system which guides the light beam to the first objective lens, approximately coincides with an optical axis of the first objective lens, wherein at least one of the optical pickup and a disc mounting unit on which the optical disc is to be mounted is inclined so that the optical pickup and the optical disc mounted on the disc mounting unit are inclined relative to each other at an angle at which initial coma aberration with respect to the first optical disc due to the first objective lens is optimally corrected, and wherein the coma aberration generating unit is not used when reproducing the first optical disc and the coma aberration generating unit is used for obtaining optimal reproducing environment when reproducing the second optical disc.

Further, according to another exemplary embodiment of the present invention, there is provided a method of manufacturing an optical pickup. Here, the optical pickup includes: a first and a second objective lenses which are configured to focus light beams having different wavelengths onto a first and a second optical discs having protection layers of different thicknesses, respectively; a coma aberration generating unit which is configured to generate coma aberration in the light beams passing through the first and/or second objective lenses; a collimating lens which is installed on a light path between a light source for emitting the light beam and the first objective lens and is configured to convert a divergent angle of the light beam passing through the collimating lens; and a collimating lens driving unit which is configured to move the collimating lens in an optical axis direction and change angles of the light beams entering into the objective lenses to correct spherical aberration, wherein the protection layer thickness of the first optical disc corresponding to the first objective lens is smaller than that of the second optical disc corresponding to the second objective lens, and wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens. In manufacturing the optical pickup having the first objective lens which is made of plastic, the method includes the steps of: installing a light guiding optical system which guides the light beam to the first objective lens to a base member; holding the first objective lens to a lens holder so that an optical axis of the light beam, which is guided by the light guiding optical system to the first objective lens, approximately coincides with an optical axis of the first objective lens; adjusting the optical pickup so that the optical pickup is inclined relative to the optical disc at an angle at which initial coma aberration with respect to the first optical disc due to the first objective lens is optimally corrected; and calculating a coma aberration correction amount in which initial coma aberration with respect to the second optical disc due to the second objective lens is optimally corrected using the coma aberration generating unit in the state where the optical pickup is inclined in the optical pickup adjusting step and storing the calculated coma aberration correction amount in a storage unit.

Further, according to another exemplary embodiment of the present invention, there is provided a method of controlling an optical pickup. Here, the optical pickup includes: a first and a second objective lenses which are configured to focus light beams having different wavelengths onto a first and a second optical discs having protection layers of different thicknesses, respectively; a coma aberration generating unit which is configured to generate coma aberration in the light beams passing through the first and/or second objective lenses; a collimating lens which is installed on a light path between a light source for emitting the light beam and the first objective lens, and is configured to convert a divergent angle of the light beam passing through the collimating lens; and a collimating lens driving unit which is configured to move the collimating lens in an optical axis direction and change angles of the light beams entering into the objective lenses to correct spherical aberration, wherein the protection layer thickness of the first optical disc corresponding to the first objective lens is smaller than that of the second optical disc corresponding to the second objective lens, wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens, and wherein the first objective lens is made of plastic and is installed so that an optical axis of the light beam, which is guided by a light guiding optical system which guides the light beam to the first and second objective lenses, approximately coincides with an optical axis of the first objective lens. In controlling the optical pickup so that the optical pickup is inclined relative to the optical disc at an angle at which initial coma aberration with respect to the first optical disc due to the first objective lens is optimally corrected, the method includes the steps of: discerning the type of the mounted optical disc; performing, when it is the first optical disc which is discerned in the discerning step, reproduction of an information signal with respect to the first optical disc without using the coma aberration generating unit; and performing, when it is the second optical disc which is discerned in the discerning step, reproduction of an information signal with respect to the second optical disc using the coma aberration generating unit.

Further, according to another exemplary embodiment of the present invention, there is provided an optical pickup including: a single objective lens which is configured to focus light beams having different wavelengths onto a first and a second optical discs having protection layers of different thicknesses, respectively; a coma aberration generating unit which is configured to generate coma aberration in the light beams passing through the objective lens; a collimating lens which is installed on a light path between a light source for emitting the light beam and the objective lens and is configured to convert a divergent angle of the light beam passing through the collimating lens; and a collimating lens driving unit which is configured to move the collimating lens in an optical axis direction and change an angle of the light beam entering into the objective lens to correct spherical aberration, wherein the protection layer thickness of the first optical disc is smaller than that of the second optical disc, wherein the objective lens satisfies, under a condition that environmental temperature is 0° C. to 70° C., the protection layer thickness of the corresponding first optical disc is 70 μm to 105 μm, and a wavelength λ1 of the light beam corresponding to the first optical disc is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens, wherein the objective lens is made of plastic and is installed so that an optical axis of the light beam, which is guided by a light guiding optical system which guides the light beam to the objective lens, approximately coincides with an optical axis of the objective lens, wherein the optical pickup is inclined relative to the optical disc at an angle at which initial coma aberration with respect to the first optical disc due to the objective lens is optimally corrected, and wherein the coma aberration generating unit is not used when reproducing the first optical disc and the coma aberration generating unit is used for obtaining optimal reproducing environment when reproducing the second optical disc.

Further, according to another exemplary embodiment of the present invention, there is provided an optical disc apparatus including an optical pickup which emits a light beam onto an optical disc which is driven to rotate, so as to perform recording and/or reproducing of an information signal. Here, the optical pickup includes: an objective lens which is configured to focus light beams having different wavelengths onto a first and a second optical discs having protection layers of different thicknesses, respectively; a coma aberration generating unit which is configured to generate coma aberration in the lights beam passing through the objective lens; a collimating lens which is installed on a light path between a light source for emitting the light beam and the objective lens, and is configured to convert a divergent angle of the light beam passing through the collimating lens; and a collimating lens driving unit which is configured to move the collimating lens in an optical axis direction and change an angle of the light beam entering into the objective lens to correct spherical aberration, wherein the protection layer thickness of the first optical disc corresponding to the first objective lens is smaller than that of the second optical disc corresponding to the second objective lens, wherein the objective lens satisfies, under a condition that environmental temperature is 0° C. to 70° C., the protection layer thickness of the first optical disc corresponding to the first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens, wherein the objective lens is made of plastic and is installed so that an optical axis of the light beam, which is guided by a light guiding optical system which guides the light beam to the objective lens, approximately coincides with an optical axis of the objective lens, wherein at least one of the optical pickup and a disc mounting unit on which the optical disc is to be mounted is inclined so that the optical pickup and the optical disc mounted on the disc mounting unit are inclined relative to each other at an angle at which initial coma aberration with respect to the first optical disc due to the objective lens is optimally corrected, and wherein the coma aberration generating unit is not used when reproducing the first optical disc and the coma aberration generating unit is used for obtaining optimal reproducing environment when reproducing the second optical disc.

Further, according to another exemplary embodiment of the present invention, there is provided a method of manufacturing an optical pickup. Here, the optical pickup includes: an objective lens which is configured to focus light beams having different wavelengths onto a first and a second optical discs having protection layers of different thicknesses, respectively; a coma aberration generating unit which is configured to generate coma aberration in the light beam passing through the objective lens; a collimating lens which is installed on a light path between a light source for emitting the light beam and the objective lens, and is configured to convert a divergent angle of the light beam passing through the collimating lens; and a collimating lens driving unit which is configured to move the collimating lens in an optical axis direction and change an angle of the light beam entering into the objective lens to correct spherical aberration, wherein the protection layer thickness of the first optical disc is smaller than that of the second optical disc, and wherein the objective lens satisfies, under a condition that environmental temperature is 0° C. to 70° C., the protection layer thickness of the corresponding first optical disc is 70 μm to 105 μm, and a wavelength λ1 of the light beam corresponding to the first optical disc is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens. In manufacturing the optical pickup having the objective lens which is made of plastic, the method includes the steps of: installing a light guiding optical system which guides the light beam to the objective lens to a base member; holding the objective lens to a lens holder so that an optical axis of the light beam which is guided by the light guiding optical system to the objective lens approximately coincides with an optical axis of the objective lens; adjusting the optical pickup so that the optical pickup is inclined relative to the optical disc at an angle at which initial coma aberration with respect to the first optical disc due to the objective lens is optimally corrected; and calculating a coma aberration correction amount in which initial coma aberration with respect to the second optical disc due to the objective lens is optimally corrected using the coma aberration generating unit in the state where the optical pickup is inclined in the optical pickup adjusting step and storing the calculated coma aberration correction amount in a storage unit.

Further, according to another exemplary embodiment of the present invention, there is provided a method of controlling an optical pickup. Here, the optical pickup includes: an objective lens which is configured to focus light beams having different wavelengths onto a first and a second optical discs having protection layers of different thicknesses, respectively; a coma aberration generating unit which is configured to generate coma aberration in the light beam passing through the objective lens; a collimating lens which is installed on a light path between a light source for emitting the light beam and the objective lens, and is configured to convert a divergent angle of the light beam passing through the collimating lens; and a collimating lens driving unit which is configured to move the collimating lens in an optical axis direction and change an angle of the light beams entering into the objective lens to correct spherical aberration, wherein the protection layer thickness of the first optical disc is smaller than that of the second optical disc, wherein the objective lens satisfies, under a condition that environmental temperature is 0° C. to 70° C., the protection layer thickness of the first optical disc corresponding to the first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens, and wherein the objective lens is made of plastic and is installed so that an optical axis of the light beam, which is guided by a light guiding optical system which guides the light beam to the objective lens, approximately coincides with an optical axis of the objective lens. In controlling the optical pickup so that the optical pickup is inclined relative to the optical disc at an angle at which initial coma aberration with respect to the first optical disc due to the objective lens is optimally corrected, the method includes the steps of: discerning the type of the mounted optical disc; performing, when it is the first optical disc which is discerned in the discerning step, reproduction of an information signal with respect to the first optical disc without using the coma aberration generating unit; and performing, when it is the second optical disc which is discerned in the discerning step, reproduction of an information signal with respect to the second optical disc using the coma aberration generating unit.

According to the embodiments of the present invention, the objective lens is made of plastic to enhance productivity and weight saving, and coma aberration due to environmental temperature changes is reduced to improve recording and/or reproducing characteristics.

### BRIEF DESCRIPTION OF THE DRAWINGS

FIG. 1 is a block diagram illustrating an optical disc apparatus according to an embodiment of the invention;

FIG. 2 is a perspective view of an optical pickup according to an embodiment of the invention;

FIG. 3 is a plan view illustrating a lens holder which holds an objective lens included in an optical pickup and a support which supports the lens holder, according to an embodiment of the invention;

FIG. 4 is a plan view illustrating an optical system included in an optical pickup according to an embodiment of the invention;

FIG. 5 is a sectional view of an optical pickup, which schematically illustrates part of a first optical system included in an optical pickup, according to an embodiment of the invention;

FIGS. 6A and 6B are diagrams illustrating relation between a first objective lens included in an optical pickup and a first light guiding optical system according to an embodiment of the invention, in which FIG. 6A is a diagram illustrating the state that an optical axis of the first objective lens and an optical axis of the first light guiding optical system are arranged to coincide with each other, and FIG. 6B is a diagram illustrating the state that an optical axis of an objective lens and an optical axis of a light guiding optical system are arranged to be inclined each other, in a comparative example for comparison with the embodiment of the invention;

FIG. 7 is a diagram illustrating the state that an optical pickup according to an embodiment of the invention is adjusted at a relative angle with respect to an optical disc;

FIG. 8 is a diagram illustrating the state that a second objective lens is driven in a tilt direction by an objective lens driving unit when using the second objective lens in the case where an optical pickup according to an embodiment of the invention is configured as shown in FIGS. 6A and 7;

FIG. 9 is a plan view illustrating a state that coma aberration is disposed toward a radial direction when first and second objective lenses included in an optical pickup according to an embodiment of the invention are installed in a lens holder;

FIG. 10 is a diagram illustrating the state that lens tilt coma aberration sensitivity is changed according to environmental temperature changes, which illustrates relation of the amount of generated coma aberration with respect to the amount of lens tilt at normal temperature and high and low temperature environments;

FIG. 11 is a diagram illustrating the state that the amount of coma aberration is changed according to change in a relative inclination angle between an optical pickup and an optical disc, which illustrates relation of the amount of generated coma aberration with respect to the amount of disc tilt;

FIG. 12 is a perspective view of an optical disc apparatus for illustrating a skew adjustment mechanism for adjusting skew of an optical pickup according to an embodiment of the invention;

FIG. 13 is a diagram for comparing variation of coma aberration due to temperature change in an optical pickup according to an embodiment of the invention and an optical pick up in the related art as adjusted in FIG. 6B, which illustrates changes in the amount of optimal disc tilt with respect to the temperature changes;

FIGS. 14A to 14C are diagrams illustrating a temperature gradient generated in a light beam passing area of first and second objective lenses included in an optical pickup according to an embodiment of the present invention, in which FIG. 14A is a perspective view illustrating temperature distribution in a region of an objective lens and a lens holder; FIG. 14B is a plan view illustrating the temperature distribution in the region of the objective lens and the lens holder; and FIG. 14C illustrates temperature changes in a sectional position of the region of the lens holder, in which the longitudinal axis represents a radial position on a straight line passing through an optical axis of the first and second objective lenses and the transverse axis represents temperature;

FIGS. 15A to 15C are diagrams for illustrating relation between the amount of coil current and coma aberration, in which FIG. 15A illustrates the coil current amount and frequency thereof, FIG. 15B illustrates the relation between the coil current amount and the coma aberration, and FIG. 15C illustrates the coma aberration and frequency thereof;

FIGS. 16A and 16B are diagrams for illustrating an installation direction of respective objective lenses in an optical pickup according to an embodiment of the present invention, in which FIG. 16A illustrates the state that the respective objective lenses are installed so that a variety of coma aberration generated in the respective objective lenses are directed in a radial direction, and FIG. 16B illustrates the state that electric current coma aberration of a first optical disc and extra-axial coma aberration of a third optical disc are reduced according to adjustment of a relative angle of the optical pickup and an optical disc;

FIGS. 17A to 17D is a diagram for illustrating a method of calculating an optimal relative angle in which coma aberration is reduced in respective cases of using first and second objective lenses in an optical pickup according to an embodiment of the present invention, in which FIG. 17A illustrates distribution obtained by a measuring device in FIG. 17B, FIG. 17B illustrates the measuring device which includes an interferometer or a wave-front sensor, and FIG. 17C illustrates distribution obtained by a measuring device in FIG. 17D, and FIG. 17D illustrates the measuring device which is monitoring spots;

FIG. 18 is a diagram for illustrating another method of calculating an optimal relative angle in which coma aberration is reduced in respective cases of using first and second objective lenses in an optical pickup according to an embodiment of the present invention, which illustrates changes in jitter, RF amplitude, TE amplitude and error rate;

FIG. 19 is a flowchart for illustrating a method of manufacturing an optical pickup according to an embodiment of the present invention;

FIG. 20 is a flowchart of a recording and/or reproducing method for illustrating a method of controlling an optical pickup according to an embodiment of the present invention;

FIG. 21 is a plan view illustrating an optical system included in an optical pickup according to another embodiment of the present invention;

FIG. 22 is a sectional view illustrating an example of an objective lens included in the optical pickup in FIG. 21;

FIGS. 23A to 23C are diagrams for illustrating relation between an objective lens included in the optical pickup in FIG. 21 and a light guiding optical system, in which FIG. 23A illustrates the state that an optical axis of the objective lens and an optical axis of the light guiding optical system coincide with each other, FIG. 23B illustrates the state that the optical pickup is adjusted at a relative angle with respect to an optical disc, and FIG. 23C illustrates the state that the objective lens is driven in a tilt direction by an objective lens driving unit when a second wavelength or the like is used, in the case where the relation is configured as shown in FIG. 23A and FIG. 23B with respect to a first wavelength; and

FIG. 24 is a plan view illustrating an optical system included in an optical pickup according to still another embodiment of the present invention.

### DESCRIPTION OF THE PREFERRED EMBODIMENTS

Hereinafter, preferred embodiments according to the present invention will be described with reference to the accompanying drawings, in the following order:

1. Overall configuration of optical disc apparatus

2. Overall configuration of optical pickup (First embodiment)

3. Temperature characteristic of lens tilt coma aberration sensitivity of objective lens

4. Correction of initial coma aberration

5. Relative angle adjustment of optical pickup with respect to optical disc

6. Functions and effects of optical pickup

7. Direction of coma aberration of objective lens and installation direction

8. Manufacturing method of optical pickup

9. Control method of optical pickup

10. Another example of optical pickup (Second embodiment)

11. Still another example of optical pickup (Third embodiment)

12. Effects of optical disc apparatus

1. Overall Configuration of Optical Disc Apparatus

Hereinafter, an optical disc apparatus which uses an optical pickup according to an embodiment of the invention will be described with reference to the accompanying drawings.

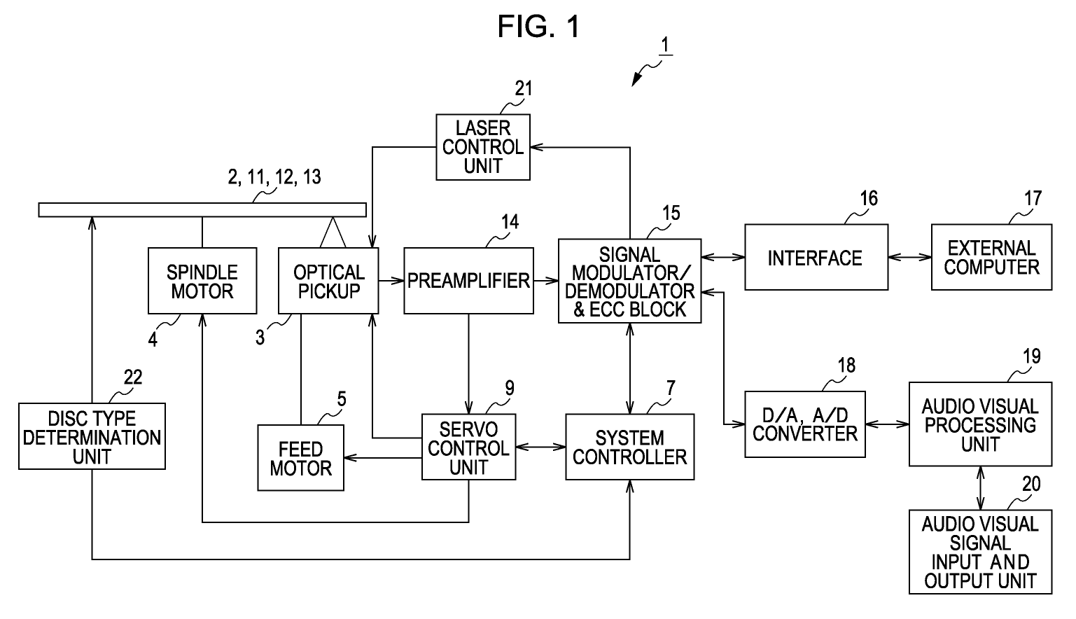

As shown in FIG. 1, an optical disc apparatus 1 according to an embodiment of the invention includes an optical pickup 3 which performs recording and/or reproducing of information from an optical disc 2, and a spindle motor 4 which is a driving unit for rotating the optical disc 2, as shown in FIG. 1. Further, the optical disc apparatus 1 includes a feed motor 5 which feeds the optical pickup 3 in a radial direction of the optical disc 2. The optical disc apparatus 1 is an optical disc apparatus which realizes compatibility between 3 standards capable of performing recording and/or reproducing of information with respect to optical discs in which three types of optical discs having different formats and recording layers are layered.

The above described optical disc 2 is a high density recording first optical disc 11 such as a BD (Blu-ray Disc (registered trademark)) capable of high density recording which uses a semiconductor laser having a short wavelength of about 405 nm (blue purple) as a light source. The first optical disc 11 has a cover layer of about 100 μm (referred to as a “prevention layer”) and is irradiated with light beams of a first wavelength of about 400 to 410 nm through the cover layer. The first optical disc includes an optical disc (the thickness of the cover layer: about 100 μm) having a single recording layer or a so-called double layer optical disc having two recording layers, and may further include a plurality of recording layers. In the case of the double layer optical disc, the thickness of a cover layer of a recording layer L0 is about 100 μm and the thickness of a cover layer of a recording layer L1 is about 75 μm.

Further, the optical disc 2 is a second optical disc 12 such as DVD (Digital Versatile Disc), DVD-R (Recordable), DVD-RW (Rewritable) or DVD+RW (Rewritable) which uses a semiconductor laser of about 655 nm wavelength as a light source. The second optical disc 12 has a cover layer of about 0.6 mm and is irradiated with light beams of a second wavelength of about 650 to 660 nm through the cover layer. A plurality of recording layers may be installed in the second optical disc 12.

In addition, the optical disc 2 is a third optical disc 13 such as CD (Compact Disc), CD-R (Recordable) or CD-RW (Rewritable) which uses a semiconductor laser of about 785 nm wavelength as a light source. The third optical disc 13 has a cover layer of about 1.2 mm and is irradiated with light beams of a third wavelength of about 760 to 800 nm wavelength through the cover layer.

Hereinafter, the optical discs which are not specified as the first to third optical discs 11, 12 and 13 simply refer to the optical disc 2.

In the optical disc apparatus 1, the spindle motor 4 and the feed motor 5 are driven according to the type of the disc by a servo control unit 9 which is controlled on the basis of a command from a system controller 7 which is a disc type discerning unit. The spindle motor 4 and the feed motor 5 are driven with predetermined revolutions according to, for example, the first optical disc 11, the second optical disc 12, and the third optical disc 13.

The optical pickup 3 is an optical pickup having three wavelength compatibility optical systems, and recording layers of optical discs having different standards are irradiated with light beams having different wavelengths through protection layers thereof. The optical pickup 3 detects reflective light of the light beams from the recording layer. The optical pickup 3 outputs a signal corresponding to each light beam from the detected reflective light.

The optical disc apparatus 1 includes a preamplifier 14 which generates a focus error signal, a tracking error signal, an RF signal or the like on the basis of the signal output from the optical pickup 3. Further, the optical disc apparatus 1 includes a signal modulator/demodulator for demodulating the signal from the preamplifier 14 or modulating a signal from an external computer 17 or the like and error correction code block (hereinafter, referred to as a signal modulator/demodulator & ECC block) 15. In addition, the optical disc apparatus 1 includes an interface 16, a D/A and A/D converter 18, an audio-visual processing unit 19, and an audio-visual signal input and output unit 20.

The preamplifier 14 generates a focus error signal on the basis of output from a photodetector using an astigmatic method or the like, and also generates a tracking error signal using a three beam method, DPD, DPP, or the like. Further, the preamplifier 14 generates an RF signal and outputs the RF signal to the signal modulator/demodulator & ECC block 15. In addition, the preamplifier 14 outputs the focus error signal and the tracking error signal to the servo control unit 9.

The signal modulator/demodulator & ECC block 15 performs the following process for a digital signal input from the interface 16 or D/A and A/D converter 18 when performing data recording with respect to the first optical disc 11. That is, the signal modulator/demodulator & ECC block 15 performs an error correction process by an error correction method such as LDC-ECC and BIS with respect to the input digital signal when recording data with respect to the first optical disc 11. Next, the signal modulator/demodulator & ECC block 15 performs a modulation process such as 1-7 PP. Moreover, when recording data with respect to the second optical disc 12, the signal modulator/demodulator & ECC block 15 performs an error correction process according to an error correction method such as PC (Product Code), and then performs a modulation process such as 8-16 modulation. Further, when recording data with respect to the third optical disc 13, the signal modulator/demodulator & ECC block 15 performs an error correction process according to an error correction method such as CIRC, and then performs a modulation process such as 8-14 modulation. Further, the signal modulator/demodulator & ECC block 15 outputs the modulated data to the laser control unit 21. Further, when performing reproduction with respect to each optical disc, the signal modulator/demodulator & ECC block 15 performs a demodulation process corresponding to the modulation method on the basis of the RF signal input from the preamplifier 14. In addition, the signal modulator/demodulator & ECC block 15 performs the error correction process to output the interface 16 or data to the D/A and A/D converter 18.

When recording data by data compression, a compression and extension unit may be installed between the signal modulator/demodulator & ECC block 15 and the interface 16 or the D/A and A/D converter 18. In this case, data is compressed by MPEG2 or MPEG4.

The focus error signal or the tracking error signal is input to the servo control unit 9 from the preamplifier 14. The servo control unit 9 generates a focus servo signal or a tracking servo signal so that the focus error signal or the tracking error signal becomes 0, and controls an objective lens driving unit such as a two axis actuator for driving an objective lens on the basis of the servo signals. In addition, a synchronization signal or the like is detected by output from the preamplifier 14, and thus, the spindle motor is servo-controlled by means of CLV (Constant Linear Velocity), CAV (Constant Angular Velocity) or a combination thereof.

The laser control unit 21 controls a laser light source of the optical pickup 3. In particular, in the specific example, the laser control unit 21 performs control so that output power of the laser light source is changed in a recording mode and a reproducing mode. Further, the laser control unit 21 performs control so that output power of the laser light source is changed according to the type of the optical disc 2. The laser control unit 21 switches the laser light source of the optical pickup 3 according to the type of the optical disc 2 detected by the disc type discerning unit 22.

The disc type discerning unit 22 may detect change in the amount of reflective light from surface reflectivity between the first optical disc 11, the second optical disc 12 and the third optical disc 13, difference in shapes and appearances or the like, and may detect different formats of the optical disc 2.

Each block for forming the optical disc apparatus 1 is configured so that a signal process based on specifications of the optical disc 2 to be installed is performed according to the detection result in the disc type discerning unit 22.

The system controller 7 controls the overall apparatus according to the type of the optical disc 2 discerned in the disc type discerning unit 22. Further, the system controller 7 controls each part according to a manipulation input from a user on the basis of address information or table of contents (TOC) recorded in a pre-mastered pit or a groove or the like which is in innermost circumference of the optical disc. That is, the system controller 7 specifies a recording location or a reproducing location of the optical disc for performing recording and reproducing on the basis of the above information, and controls each part on the specified location.

The optical disc apparatus 1 having such a configuration rotates the optical disc 2 by the spindle motor 4. Further, the optical disc apparatus 1 controls driving of the feed motor 5 according to a control signal from the servo control unit 9, and moves the optical pickup 3 to a location corresponding to a desired recording track of the optical disc 2, to thereby perform recording and reproducing of information with respect to the optical disc 2.

Specifically, when the recording and reproducing of the information is performed by the optical disc apparatus 1, the servo control unit 9 rotates the optical disc 2 by means of the CAV or CLV or the combination thereof. The optical pickup 3 emits light beams by the light source thereof and detects the light beams returning from the optical disc 2 by the photodetector thereof, and to generate the focus error signal or the tracking error signal. In addition, the optical pickup 3 drives the objective lens by the objective lens driving mechanism on the basis of the focus error signal or the tracking error signal to perform a focus servo and a tracking servo.

In addition, when the information is recorded by the optical disc apparatus 1, a signal from the external computer 17 is input to the signal modulator and demodulator & ECC block 15 through the interface 16. The signal modulator/demodulator & ECC block 15 adds the above described predetermined error correction code to digital data input from the interface 16 or the A/D converter 18, and performs a predetermined modulation process to then generate a recording signal. The laser control unit 21 controls the laser light source of the optical pick up 3 on the basis of the recording signal generated in the signal modulator and demodulator & ECC block 15 to record the information in a predetermined optical disc.

Further, when the information recorded in the optical disc 2 is reproduced by the optical disc apparatus 1, the signal modulator and demodulator & ECC block 15 performs a demodulating process with respect to the signal detected by the photodetector. If the recording signal demodulated by the signal modulator and demodulator & ECC block 15 is used for data storage of the computer, the recording signal is output to the external computer 17 through the interface 16. Accordingly, the external computer 17 may operate on the basis of the signal recorded in the optical disc 2. Further, if the recording signal demodulated by the signal modulator and demodulator & ECC block 15 is used for audio-visual, the recording signal is converted from digital to analog in the D/A converter 18 to be supplied to the audio-visual processing unit 19. The audio-visual process is performed in the audio-visual processing unit 19, and is output to an external speaker or monitor (not shown) through the audio-visual signal input and output unit 20.

2. Overall Configuration of Optical Pickup (First Embodiment)

Next, an optical pickup 3 according to an embodiment of the invention will be described in detail. Hereinafter, the optical pickup 3 performs recording or reproducing of an information signal with respect to three different types of optical discs 11, 12 and 13, but this is not limitative but used as an example. For example, the recording and reproducing may be performed with respect to two different types of optical discs 11 and 12.

The optical pickup 3 according to the embodiment of the invention includes first and second light sources 31 and 32 which include a semiconductor laser or the like which emits a plurality types of light beams having the above described different wavelengths. Further, the optical pickup 3 includes a photodiode as a light detecting element which detects the reflective light beams reflected from a signal recording surface of the optical disc 2. In addition, the optical pickup 3 includes an optical system which guides the light beams from the first and second light sources 31 and 32 to the optical disc 2, and guides the light beam reflected in the optical disc 2 to the light detecting element.

Here, the first optical source 31 includes a light emitting unit which emits light beams having a first wavelength which is a design wavelength of about 405 nm corresponding to the first optical disc 11. The second optical source 32 includes a light emitting unit which emits light beams having a second wavelength which is a design wavelength of about 655 nm corresponding to the second optical disc 12. Further, the second optical source 32 includes a light emitting unit which emits light beams having a third wavelength which is a design wavelength of about 785 nm corresponding to the third optical disc 13. In the second light source 32, the second wavelength light emitting unit and the third wavelength light emitting unit are arranged in parallel in a direction corresponding to a direction of coma aberration of a second objective lens 34 which will be described later.

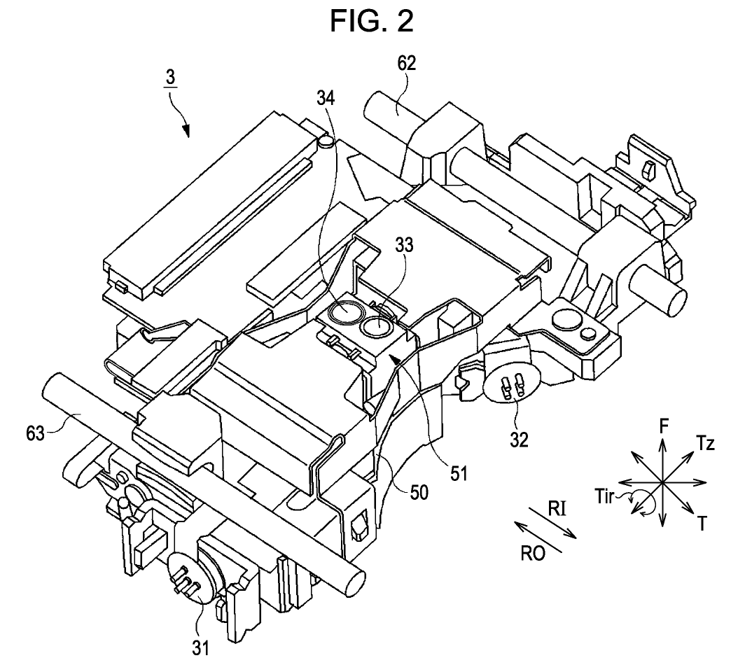

As shown in FIG. 2, the optical pickup 3 is installed on a pickup base 50 which is an installation base of a variety of components which is installed to move in a radial direction R of the optical disc 2 inside of a case of the optical disc apparatus 1. The pickup base 50 serves as a so-called slide base, and is coupled with a main shaft 62 and a sub shaft 63 which are guide shafts installed in a chassis of the optical disc apparatus 1. The pickup base 50 is supported on the main shaft 62 and the sub shaft 63 to move in a radial direction thereof. An arrow RI in FIG. 2 and subsequent figures refer to a direction toward inner circumference among the radial direction and an arrow RO refers to a direction toward outer circumference among the radial direction.

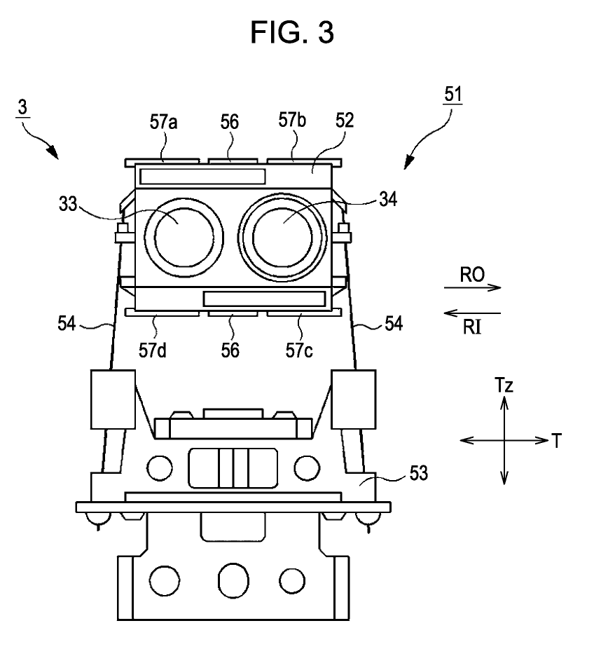

Further, as shown in FIG. 3, the optical pickup 3 includes a lens holder 52 which holds a plurality of objective lenses 33 and 34 which focuses the light beams emitted from the light source and exits the focused light beams to the optical disc. The lens holder 52 serves as an actuator driving unit and is supported to be displaced in a tracking direction or in a focus direction, through a plurality of suspensions 54 which serves as support arms, on a support 53 which serves as an actuator supporting unit. Here, the support 53 is arranged with an interval in a tangential direction Tz from the lens holder 52 and is installed on the pickup base 50. Further, the suspensions 54 which are the support arms supports the lens holder 52 to move in the focus direction F and the tracking direction T with respect to the support 53.

The lens holder 52, the support 53 and the suspensions 54 form the objective lens driving unit 51, in combination with respective coils 56, 57a to 57d and a magnet 58 which will be described later. The objective lens driving unit 51 drives the objective lenses 33 and 34 in the focus direction F and the tracking direction T. Further, the objective lens driving unit 51 serves as a tilt correction mechanism which drives the lens holder 52 which supports the first and second objective lenses 33 and 34 in a tilt direction Tir to be inclined. In this way, the objective lens driving unit 51 is a so-called tri-axial actuator which is capable of driving the lens holder 52 and the objective lenses supported by the lens holder 52 in the focus direction, the tracking direction and the tilt direction.

Further, the first and second objective lenses 33 and 34 form part of the optical system of the optical pickup 3. The first objective lens 33 is a single objective lens made of plastic with an aperture ratio (NA) of about 0.85. The second objective lens 34 is a single objective lens made of plastic with an aperture ratio (NA) of about 0.6 to 0.65 with respect to a second wavelength and with an aperture ratio (NA) of about 0.45 to 0.53 with respect to a third wavelength. The plastic first and second objective lenses 33 and 34 may enhance productivity or weight saving compared with glass lenses in the related art. A configuration of the optical pickup 3 which will be described hereinafter is provided to solve problems which may be generated in the case where the first objective lens 33 corresponding to a high density recording optical disc such as BD is made of plastic. Accordingly, the second objective lens 34 is not limited to the plastic, for example, may be formed of glass.

In the optical pickup 3, the plurality of objective lenses 33 and 34 is arranged in parallel in the radial direction R (tracking direction T), but the number and arrangement of the objective lenses are not limited thereto. For example, the plurality of objective lenses may be arranged in the tangential direction Tz.

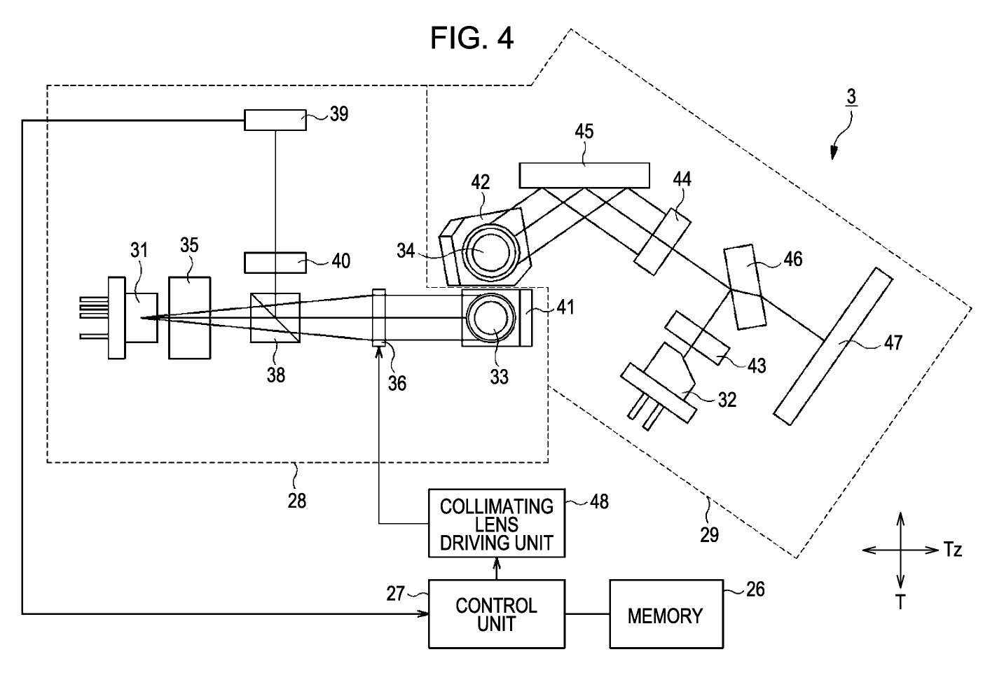

As the optical system which guides the light beams emitted from the first and second light sources 31 and 32 to the optical disc 2, first and second optical systems are exemplified. The first optical system guides the light beam of a first wavelength emitted from the first light source 31 to the optical disc 2 which is the first optical disc 11 through the first objective lens 33. As shown in FIG. 4, such a first optical system includes a first light guiding optical system 28 which guides the light beam of the first wavelength to the first objective lens 33, and the first objective lens 33. The second optical system guides the light beams emitted from the second light source 32 to the optical disc 2 which is the second or third optical disc 12 or 13 through the second objective lens 34. As shown in FIG. 4, such a second optical system includes a second light guiding optical system 29 which guides the light beam of second and third wavelengths to the second objective lens 34, and the second objective lens 34.

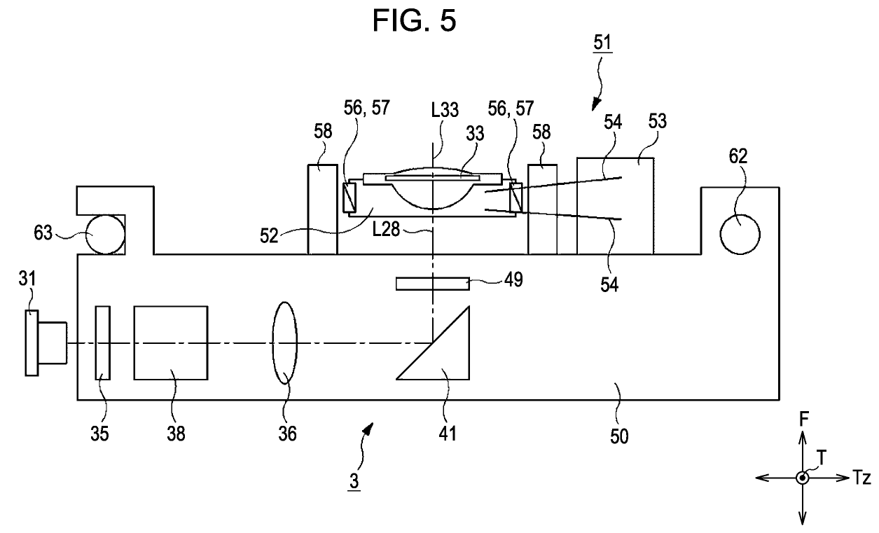

Firstly, the first light guiding optical system 28 which forms the first optical system will be described with reference to FIG. 4. The first light guiding optical system 28 includes a first grating 35 which diffracts the light beam of the first wavelength emitted from the first light source 31 and divides the diffracted light beam into at least three beams so as to detect a tracking error signal or the like. Further, the first light guiding optical system 28 includes a first collimating lens 36 which is a divergent angle converting element which converts a divergent angle of the light beam diffracted by the first grating 35 into, for example, approximately parallel light beams of a desired angle. In addition, the first light guiding optical system 28 includes a first raising mirror 41 which reflects the approximately parallel light beams converted by the first collimating lens 36 and guides the reflected light beams toward the first objective lens 33 and the optical disc 2. Moreover, the first light guiding optical system 28 includes a quarter-wavelength plate 49 which is installed between the first raising mirror 41 and the first objective lens 33 and provides a phase difference of ¼ wavelength to an incident optical beam (see FIG. 5). FIG. 4 is a plan view for illustrating location relation of the respective optical components and the objective lenses, which does not illustrate the quarter-wavelength plate 49 for simplicity of illustration in FIG. 4, but the quarter-wavelength plate 49 is arranged as shown in FIG. 5. The first objective lens 33 which forms the first optical system focuses the light beam which is set-up by the first raising mirror 41 and passes the quarter-wavelength plate 49 on a recording surface of the optical disc. Further, the first light guiding optical system 28 includes a polarized beam splitter 38 which is installed between the first grating 35 and the first collimating lens 36. The first polarized beam splitter 38 of the first light guiding optical system 28 includes a function for splitting a light path of the light beam which is focused by the first objective lens 33 and reflected by the optical disc from a light path of the light beam emitted from the first light source 31. In addition, the first light guiding optical system 28 includes a first photodetector 39 which receives and detects the returning light beam split by the polarized beam splitter 38. Moreover, the first light guiding optical system 28 includes a multi-lens 40 which is installed between the polarized beam splitter 38 and the first photodetector 39 and focuses the returning light beam which is split by the polarized beam splitter 38 onto a light-sensing surface of the first photodetector 39. The first photodetector 39 senses the light beam which is focused by the multi-lens 40 in the light-sensing surface, outputs an information signal (RF signal) to the preamplifier 14, detects a variety of signals such as a tracking error signal and a focus error signal, and outputs the signals to the servo control unit 9.

The first collimating lens 36 which is included in the first light guiding optical system 28 is moved so as to correct spherical aberration generated, for example, by temperature changes, errors in the thickness of a cover layer or the like, and converts the divergent angle of the light beam which is incident to the first objective lens 33 according to the location thereof. That is, the first collimating lens 36 may be moved in an optical axis direction. A collimating lens driving unit 48 which drives the first collimating lens 36 to move in the optical axis direction is installed in the optical pickup 3. The collimating lens driving unit 48 may rotate a lead screw, for example, by a feed motor to move the first collimating lens 36. The collimating lens driving unit 48 may move the first collimating lens 36 by working in tandem with electric current flowing in a magnet and a coil as in the objective lens driving unit. Further, a linear motor or the like may be used. The first collimating lens 36 moves so that the light beam enters into the first objective lens 33 in a state of a convergent light beam which is slightly converged or in a state of a divergent light beam which is slightly diverged, compared with a parallel light beam, thereby reducing the generated spherical aberration. In this way, the collimating lens driving unit 48 corrects the spherical aberration by moving the first collimating lens 36 in the optical axis direction, changing the angle of the light beam entering into the first objective lens 33 and changing an incident magnification ratio.

A control unit 27 which performs a calculation for adjusting a location of the first collimating lens 36 according to temperature changes or errors in the thickness of the cover layer is installed in the first optical pickup 3. An RF signal is input to the control unit 27 from the first photodetector 39. The control unit 27 monitors the amount of jitter in the input RF signal and drives the collimating lens driving unit 48 to move the first collimating lens 36, to thereby perform the spherical aberration correction. In order to perform the location adjustment of the first collimating lens 36 according to the temperature changes, a temperature detecting element may be installed adjacent to the objective lens. In such a case, a temperature signal from the temperature detecting element is input to the control unit 27. In this case, the control unit 27 drives the collimating lens driving unit 48 on the basis of the temperature signal or the amount of jitter in the temperature signal and the RF signal to perform the spherical aberration correction.

In the case where the optical pickup performs recording and reproducing of an information signal with respect to an optical disc having a plurality of recording layers, the first collimating lens 36 moves to an appropriate location for every recording layer. At this time, the first collimating lens 36 moves to the appropriate location for every recording layer by detecting change in surface reflectivity and reading the information signal by focus search. At this time, the first collimating lens 36 moves to the location according to each recording layer to reduce the spherical aberration due to differences in thicknesses up to a surface of a light incident side of the optical disc from each recording layer (referred to as “the thickness of the cover layer”). That is, the first collimating lens 36 and the collimating lens driving unit 48 may appropriately form a beam spot of the light beam with respect to each of the plurality of recording layers. In this way, the first collimating lens 36 and the like may be driven to move in the optical axis direction to change an incident magnification ratio of the light beam directing to the first objective lens 33, to thereby reduce the spherical aberration generated by the temperature changes or the changes in the thickness of the cover layer, and to form an appropriate beam spot.

As described above, the first collimating lens 36 and the collimating lens driving unit 48 serve as an incident magnification ratio charging unit which charges the incident magnification ratio of the light beam to the first objective lens 33. Here, the incident magnification ratio variation unit included in the optical pickup 3 is not limited thereto, and may be a so-called beam expander, a liquid crystal element or the like.

The first objective lens 33 included in the first optical system is held to move by the objective lens driving unit 51 installed in the optical pickup 3, as described above. The first objective lens 33 is displaced by the objective lens driving unit 51 on the basis of the tracking error signal and the focus error signal generated by the returning light from the optical disc 2 detected by the first photodetector 39. Accordingly, the first objective lens 33 is displaced in a biaxial direction of a direction (focus direction) spaced adjacent to the optical disc 2 and a radial direction (tracking direction) of the optical disc 2. The first objective lens 33 focuses the light beam so that the light beam from a first light emitting unit is constantly focused on the recording surface of the optical disc 2, and makes the focused light beam follow a recording track formed on the recording surface of the optical disc 2. The objective lens driving unit 51 serves as a tilt correction mechanism which inclines the lens holder 52 in a tilt direction, but does not perform the inclination in the tilt direction in the case where the first objective lens 33 is used. In other words, when performing recording and reproducing with respect to the first optical disc, the tilt correction mechanism is not used, and even though temperature environments of the objective lens and the peripheral components thereof are changed, a current state thereof is maintained. That is, the objective lens driving unit 51 does not perform the inclination in the tilt direction of the lens holder 52.

Further, when there is a change in the thickness of the cover layer of the optical disc 2 by the conversion of the recording layer or manufacturing errors or when there is a environment temperature change, the light beam which has the changed incident magnification ratio by moving the collimating lens 35 to the optical axis direction enters into the first objective lens 33. The first objective lens 33 constantly corrects, that is, reduces the spherical aberration by the change in the incident magnification ratio.

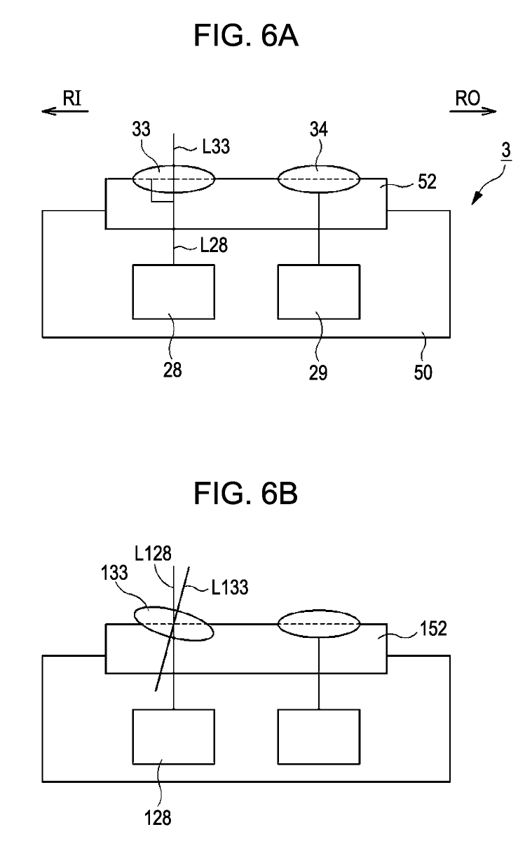

Further, as shown in FIG. 5 and FIG. 6A, the first objective lens 33 is installed so that an optical axis L28 of the light beam guided by the first light guiding optical system 28 approximately coincides with an optical axis L33 of the first objective lens 33. Here, as described above, the first light guiding optical system 28 refers to optical components other than the first objective lens 33 which is installed to be driven in the objective lens driving unit 51, among the first optical system corresponding to the first optical disc. The optical axis of the first objective lens 33 refers to an axis which connects optical surfaces of the incident side and an exiting side which form the first objective lens 33. The first objective lens 33 is not installed by inclination adjustment in consideration with initial coma aberration of the light guiding optical system, the objective lens and the like as in the related art when the first objective lens 33 is installed in the lens holder 52, and is but installed to coincide with the optical axis of the first light guiding optical system 28. In this respect, in the “assembling adjustment of the objective lens” in the related art, the adjustment is performed as shown in a comparative example in FIG. 6B. In the case of the comparative example in FIG. 6B, an optical axis L₁₃₃ of the objective lens 133 is inclined with respect to an optical axis L128 of the light guiding optical system 128 by initial coma aberration and is assembled in the lens holder 52. Meanwhile, in the optical pickup 3 as shown in FIG. 6A, the first objective lens 33 is adjusted in an optical axis thereof to be installed in the lens holder 52 in a reference state which is not displaced. Specifically, the first objective lens 33 is installed so that the optical axis of the light beam, which is guided by the first light guiding optical system 28 and enters into the first objective lens 33, approximately coincides with the optical axis of the first objective lens 33. Here, the approximate coincidence may include the range of installation errors, and it is possible to sufficiently obtain effects which will be described later in the case where angles between the optical axis of the light beam, which is guided by the first light guiding optical system 28 and enters into the first objective lens 33, and the optical axis of the first objective lens 33 is within 0±0.25°. The so-called initial coma aberration of the various optical components of the light guiding optical system or the objective lens 33 may be removed by inclining the optical pickup 3 with respect to the optical disc in a relative tilt direction, which will be described later.

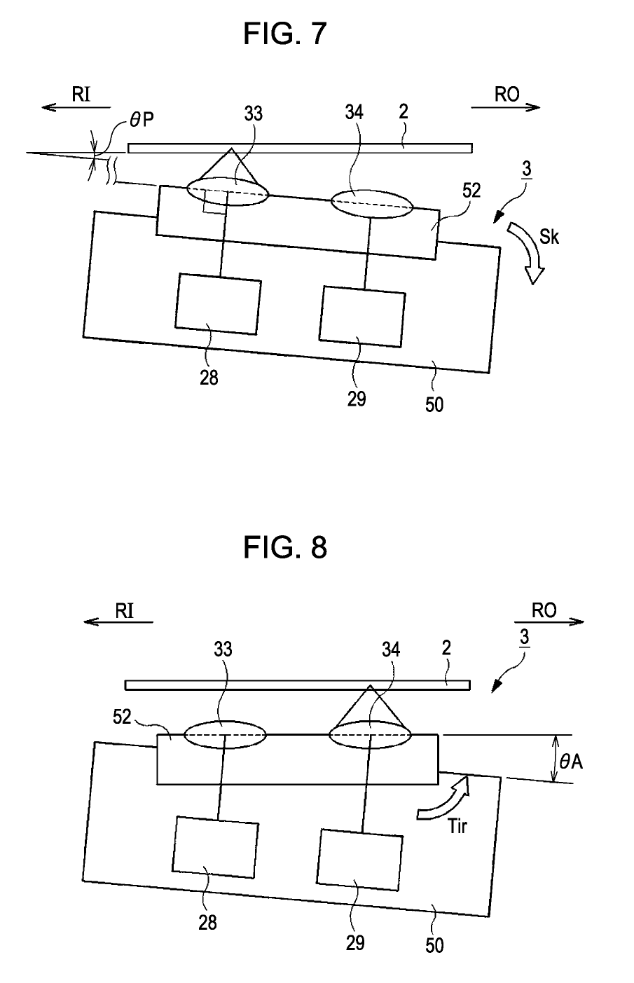

In this way, when the optical pickup 3 having the first optical system forms the optical disc apparatus 1, the tilt angle of the optical pickup 3 is adjusted as shown in FIG. 7, to thereby prevent the initial coma aberration generated when the first objective lens 33 is used. Specifically, the adjustment of the tilt angle of the optical pickup 3 will be described in detail later in “5. Relative angle adjustment with respect to optical disc of optical pickup”. Further, the objective lens driving unit 51 does not serve as the tilt correction mechanism when the optical disc having a thickness t1 of the cover layer is reproduced using the first objective lens 33. In such a case, the optical pickup 3 performs recording and reproducing while maintaining a current state thereof, even though temperature environments of the first objective lens 33 or the peripheral components thereof are changed.

Next, the second light guiding optical system 29 included in the second optical system will be described with reference to FIG. 4. The second light guiding optical system 29 at least includes a second grating 43 which diffracts the light beam of the second and third wavelengths emitted from the second light source 32 and divides the diffracted light beam into at least three beams. Further, the second light guiding optical system 29 includes a second collimating lens 44 which converts a divergent angle of the light beam diffracted by the second grating 43 into approximately parallel light beams. In addition, the second light guiding optical system 29 includes a bent up mirror 45 which reflects the approximately parallel light beams converted by the second collimating lens 44 and changes the light path of the light beams in a surface approximately perpendicular to a focus direction F. Moreover, the second light guiding optical system 29 includes a second raising mirror 42 which re-reflects the light beam reflected from the bent up mirror 45 and guides the re-reflected light beam toward the second objective lens 34 and the optical disc 2. In the second light guiding optical system 29, a quarter-wavelength plate may be installed between the second raising mirror 42 and the second objective lens 34, as in the above described first light guiding optical system. Further, the second objective lens 34 included in the second optical system focuses the light beam which is raised by the second raising mirror 42 on a signal recording surface of the optical disc. Further, the second light guiding optical system 29 includes a beam splitter 46 which is installed on the light path between the second grating 43 and the second collimating lens 44. The beam splitter 46 of the second light guiding optical system 29 splits a light path of the returning light beam which is focused by the second objective lens 34 and reflected by the optical disc from a light path of the light beam emitted from the second light source 32. The second light guiding optical system 29 includes a second photodetector 47 which receives and detects the returning light beam split by the beam splitter 46. Moreover, the second photodetector 47 receives the light beam in the light-receiving surface, outputs an information signal (RF signal) to the preamplifier 14, detects a variety of signals such as a tracking error signal and a focus error signal, and outputs the signals to the servo control unit 9.

As described above, the second collimating lens 34 including the second optical system is held to move by the objective lens driving unit 51 installed in the optical pickup 3. The second objective lens 34 is displaced by the objective lens driving unit 51 on the basis of the tracking error signal and the focus error signal generated by the returning light from the optical disc 2 which is detected by the second photodetector 47. Accordingly, the second objective lens 34 is displaced in the biaxial direction of the focus direction and the tracking direction. The second objective lens 34 focuses the light beam in order to constantly focus the light beam from the second and third light emitting units on the recording surface of the optical disc 2, and makes the focused light beam follow a recording track formed on the recording surface of the optical disc 2. The second objective lens 34 may be inclined in the tilt direction of the objective lens 34 as well as the above described biaxial direction, and may be inclined in a tilt direction Tir by the objective lens driving unit 51 as shown in FIG. 8. That is, the second objective lens 34 is inclined in the tilt direction by the objective lens driving unit 51 by a predetermined optimal angle which is determined in advance so as to most remarkably reduce the coma aberration as described later. The second objective lens 34 which is inclined in the tilt direction may set the optical pickup 3 so that the first objective lens 33 is in an optimal state as shown in FIG. 7, in the case where two objective lenses are installed in the common lens holder 52. That is, the second objective lens 34 is tilt-driven in the case where the second objective lens 34 is used in the state that the optical pickup 3 is set as shown in FIG. 7, to thereby performing recording and reproducing in the optimal state. Here, the second objective lens 34 is statically tilt-driven in the case of using the corresponding lens, but may be dynamically tilt-driven. For example, the second objective lens 34 may be inclined in the corresponding tilt direction by the objective lens driving unit 51 on the basis of the RF signal or the like detected by the second photodetector 47. With such a configuration, the second objective lens 34 may further reduce the coma aberration. Further, the objective lens driving unit 51 which is the above described tilt correction mechanism generates the coma aberration to be offset in the light beam entering into the second objective lens 34 to reduce the coma aberration. That is, the objective lens driving unit 51 serves as a coma aberration generating unit, but the coma aberration may be adjusted by installing the liquid crystal element or the like as described later.

In this way, the objective lens driving unit 51 does not perform the inclination in the tilt direction in the case where the first objective lens 33 is used, but performs the inclination in the tilt direction in the case where the second objective lens 34 is used. In other words, when performing recording and reproducing with respect to the second optical disc, the lens holder 52 is inclined using the objective lens driving unit 51 which is the tilt correction mechanism in order to obtain an optimal recording environment.

Here, as shown in FIG. 2, the tilt direction refers to a so-called radial tilt direction Tir which is an axial rotational direction which centers around a tangential direction Tz perpendicular to the above described focus direction F and tracking direction T, but is not limited thereto. That is, the second objective lens 34 may be driven in a so-called tangential tilt direction which is an axial rotational direction which centers around the tracking direction. However, since the coma aberration of the objective lenses 33 and 34 is arranged in the radial direction in the optical pickup 3 as described later, it is necessary to drive the objective lenses in the radial tilt direction Tir. Further, in the case where the tilt correction is dynamically performed, the objective lenses may be driven in a quadra-axial direction in which it may be driven in the radial tilt direction and the tangential tilt direction.

The second optical system may be configured to drive the collimating lens, and may be configured to correct the spherical aberration in the temperature change or the like, similarly to the above described first optical system. In addition to such a configuration, when there is a change in an incident magnification ratio according to the environment temperature change, the second objective lens 34 may be inclined in the tilt direction by the objective lens driving unit 51, to thereby remove the coma aberration.

Further, the second objective lens 34 is preferably installed so that an optical axis of the light beam, which is guided by the second light guiding optical system 29, approximately coincides with an optical axis of the light beam of the second objective lens 34. Here, as described later, since two objective lenses are installed in the common lens holder 52, the optical axis of the above described objective lens 33 is firstly adjusted.

In the above description, exclusive optical components are installed in each of the first optical system 28 corresponding to the first optical disc and the second optical system 29 corresponding to the second and third optical discs, but this configuration is not limitative but used as an example. That is, compatible optical components may be commonly employed in the first and second optical systems.

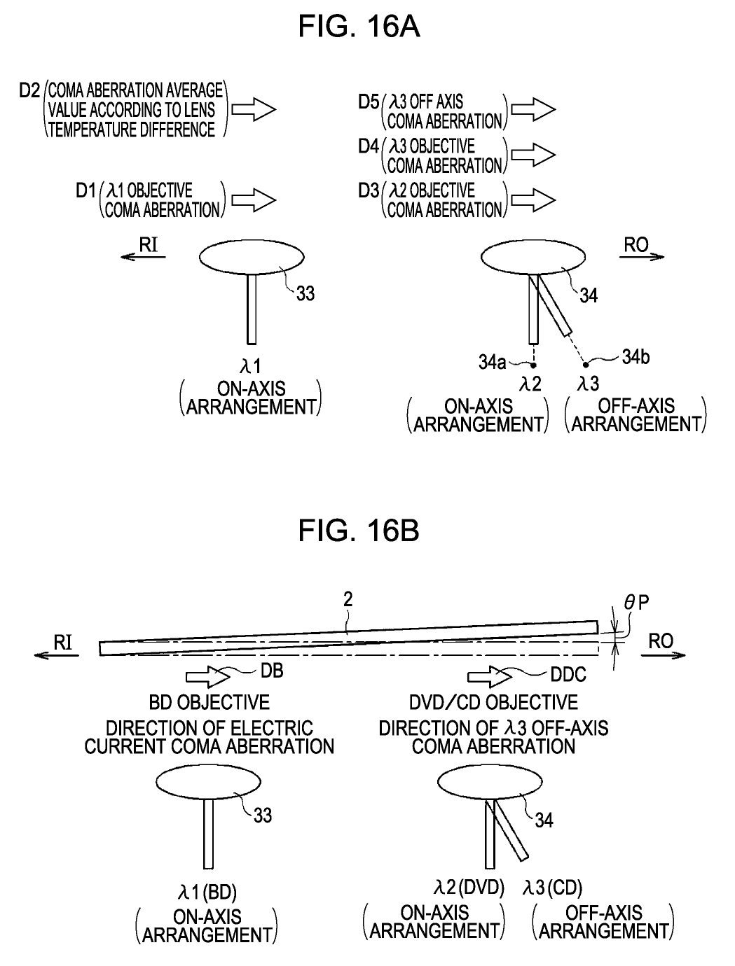

However, the above described first and second objective lenses 33 and 34 are assembled in the lens holder 52 so that the directions of the coma aberrations are approximately constant. In this way, an optical pickup 3 which is mounted with two or more objective lenses has a characteristic so that the directions of the coma aberrations of the respective objective lenses 33 and 34 are configured to be approximately the same, to thereby assemble the first and second objective lenses 33 and 34 in the objective lens driving unit 51 which is the actuator. With such a configuration, as described in FIG. 7, the optical pickup 3 is inclined so that the first objective lens 33 is in an optimal state, which may also advantageously operate the second objective lens 34 (see FIG. 16B). In other words, error variation from optimal inclination locations of both objective lenses may be effectively reduced.

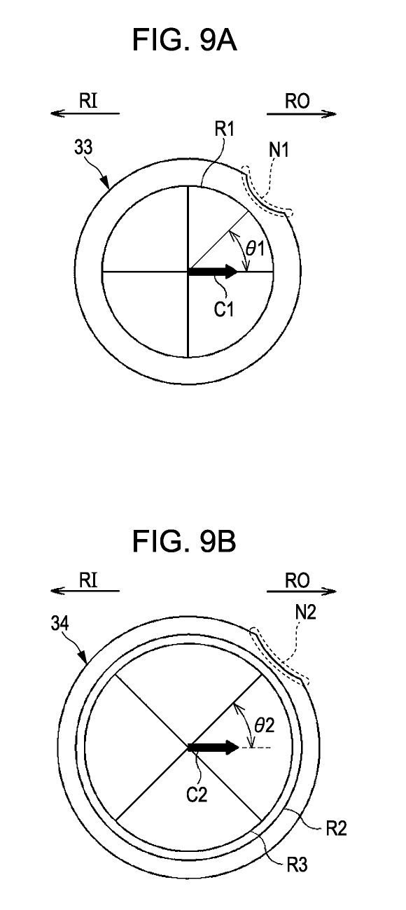

Further, in the optical pickup 3 according to the present embodiment, as shown in FIG. 9, each of the first and second objective lenses 33 and 34 is assembled in the lens holder 52 so that the coma aberration is arranged in a radial direction, for example, toward the external side RO. Alternatively, the first and second objective lenses 33 and 34 may be configured so that the coma aberration is arranged toward the inner side RI.

Here, a specific installation method will be described. The first and second objective lenses 33 and 34 detect which region the coma aberration is directed toward, among regions divided by a predetermined division number in a circumferential direction, respectively. For example, the first and second objective lenses 33 and 34 detect which region the coma aberration is directed toward, among the equally divided regions in the planar surface perpendicular to the optical axis, and thus, it is recognized that a direction of an intermediate location of the corresponding region is the direction of the coma aberration. Recognition units N1 and N2, such as a gate-cut, indicating the direction of the coma aberration are installed in the first and second objective lenses 33 and 34 in a region other than an effective region through which the light beam passes. In the figure, a region R1 in the figure represents the effective region with respect to the light beam of the first wavelength of the first objective lens 33, and regions R2 and R3 represent effective regions with respect to the light beams of the second and third wavelengths of the second objective lens 34, respectively. In the case where the objective lens made of plastic is used, since cavity as a manufacturing factor thereof is constant, directions of coma aberration are approximately constant for every lot, and thus, it is conceivable to measure directions of the plurality of coma aberration in every lot of the manufactured lenses. In this case, with respect to directions in which the gate-cuts N1 and N2 are installed, angles θ1, θ2 of middle locations of the gate-cuts N1 and N2 with respect to directions C1 and C2 are detected. Here, it is recognized that the coma aberration is arranged in directions shifted by the predetermined angles θ1 and θ2 with respect to the gate-cuts N1 and N2, and accordingly, the first and second objective lenses 33 and 34 are assembled in the lens holder 52. The recognition units indicating the direction of such coma aberration is not limited to the gate-cuts, and may be provided as scale lines. Further, the recognition units may be configured to include both of the gate-cuts and the scale lines, and may perform installation with higher accuracy in such a case. In addition, on the basis of the recognition units N1 and N2, the first and second objective lenses 33 and 34 in which the directions C1 and C2 of the coma aberrations are recognized are assembled in the lens holder 52 so that the directions of the coma aberrations are directed to the radial direction.

However, as shown in FIGS. 3 and 5, a tracking coil 56 which generates a driving force in the tracking direction T which is the approximately radial direction of the optical disc 2 is installed in the lens holder 52 on which the above described objective lenses 33 and 34 are held. Further, focus coils 57a to 57d which generate a driving force in the focus direction F which is close to and spaced from the optical disc are installed in the lens holder 52.

A magnet 58 which is arranged on the pickup base 50, being opposite to the tracking coil 56 and the focus coils 57a to 57d and provides a predetermined magnetic field to the tracking coil 56 and the focus coils 57a to 57d.

A driving electric current is supplied to the tracking coil 56 and the focus coils 57a to 57d. If the electric current is supplied to each coil, the objective lens driving unit 51 drives to displace the lens holder 52 in the tracking direction T and the focus direction F by interaction of the electric current supplied to each coil and the magnetic field from the magnet.

As a result, the first and second objective lenses 33 and 34 which are supported by the lens holder 52 are driven to be displaced in the focus direction F and/or the tracking direction T. That is, a focus control is performed so that the light beam which is incident to the optical disc through the first and second objective lenses 33 and 34 is focused on a signal recording surface of the optical disc. Further, a tracking control is performed so that the light beam which passes through the first and second objective lenses 33 and 34 follows a recording track formed in the optical disc.

In addition, the objective lens driving unit 51 causes difference in the driving forces of the focus coils 57a and 57d and the focus coils 57b and 57c which are arranged in parallel with the tracking direction T, to thereby drive the lens holder 52 to be displaced in the radial tilt direction Tir.

As a result, the second objective lens 34 which is supported by the lens holder 52 is driven to be displaced in the tilt direction, and thus, the coma aberration in the case where the light beam is focused using the second objective lens 34 may be reduced. That is, a spot shape due to the light beam incident to the light disc through the second objective lens 34 may be adjusted to become an optimal state.

Here, the tilt driving is performed by making the difference in the driving forces of the focus coils 57a to 57d, but the configuration is not limitative but used as an example. Further, a tilt coil and a tilt coil magnet may be installed and then a variety of tilt controls may be performed.

The optical pickup 3 having such a configuration emits a light beam having a wavelength corresponding to the type of the optical disc among light beams of first to third wavelengths from the light emitting units which is installed in the first and second light sources 31 and 32, according to the type of the installed optical discs. Further, the optical pickup 3 drives to displace the first or second objective lens 33 or 34 on the basis of a focus servo signal and a tracking servo signal generated by the returning light detected by the first and second photodetectors 39 and 47. Accordingly, the optical pickup 3 performs a focus servo and a tracking servo. In the optical pickup 3, the first and second objective lenses 33 and 34 is driven to be displaced, and moves to a focus location with respect to the signal recording surface of the optical disc 2. Thus, the optical pickup 3 performs recording or reproducing of an information signal with respect to the optical disc 2 with the light beam being focused on the recording track of the optical disc 2.

In addition, the optical pickup 3 improves productivity or weight saving by using the first objective lens 33 made of plastic as components thereof. Further, the optical pickup 3 solves problems due to changes in lens tilt com aberration sensitivity according to temperature change by using the plastic first objective lens 33 corresponding to the high density recording optical disc such as BD. In this respect, “3. Temperature characteristic of lens tilt coma aberration sensitivity of objective lens” will be described hereinafter.

3. Temperature Characteristic of Lens Tilt Coma Aberration Sensitivity of Objective Lens

Next, a temperature characteristic of the lens tilt coma aberration sensitivity of the first objective lens 33 included in the optical pickup 3 according to the present embodiment will be described.

As described before, the plastic objective lens has a considerable change of spherical aberration due to environment temperature change compared with glass products, and causes deterioration in recording and reproducing characteristics. In particular, in the optical disc capable of recording with a high density in high numerical aperture, such characteristic deterioration may cause a significant problem. In this respect, as described above, by changing an incident angle of the light beam which is incident to the first objective lens 33 by driving the first collimating lens 36, that is, by changing an incident magnification ratio, the spherical aberration may be corrected. At this time, by changing the incident angle of the light beam with respect to the first objective lens 33, the amount of coma aberration generated when the objective lens is inclined (referred to as “lens tilt”) is changed.

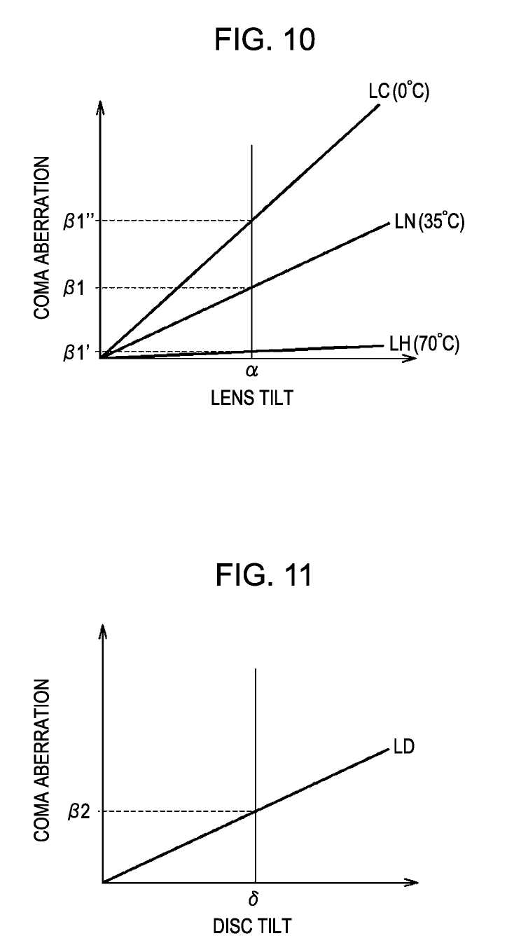

Specifically, as shown in FIG. 10, if the lens tilt coma aberration sensitivity is in a state indicated by LN in a normal temperature of about 35° C., the lens tilt coma aberration sensitivity is decreased to LH in a high temperature of about 70° C. On the other hand, in a low temperature of about 0° C., the lens tilt coma aberration sensitivity is increased to LC. In this way, FIG. 10 represents that the coma aberration generated at the same lens tilt angle is significantly changed according to the change in the incident magnification ratio by driving the collimating lens. In other words, the coma aberration corresponding to the lens tilt angle is significantly changed according to the environment temperature change.

Further, if such a plastic objective lens is installed in the lens holder of the actuator in the state that the objective lens is inclined in order to correct the coma aberration, similarly to the glass lens in the related art, there occur the following problems. That is, in installation of the objective lens in the related art, a method is used that the objective lens is inclined to be installed in the lens holder, in order to remove coma aberration generated by the objective lens or components included in the light guiding optical system, or assembly accuracy of these components. This has been described above with reference to FIG. 6B. Accordingly, in a normal temperature, the coma aberration may be set to almost 0. That is, in the normal temperature, the amount of coma aberration to be corrected and the amount of coma aberration generated by the inclination adjustment of the objective lens are the same.

However, as shown in FIG. 10, since the lens tilt coma aberration sensitivity is changed according to the change in the incident magnification ratio due to the temperature change, under high and low temperature environments, the amount of the coma aberration generated by the inclination adjustment of the objective lens is changed as indicated by the solid lines LH and LC. Further, as in the high and low temperature environments, in the case where the lens tilt coma aberration sensitivity is changed, the coma aberration remains as a result or further significant coma aberration is generated.

In this respect, more specifically, it is assumed that the coma aberration generated by optical components included in the optical pickup or assembly errors of the components is Y. In this case, the objective lens is inclined in a direction in which coma aberration is offset by the amount of lens tilt α satisfying Y=β1 using β1/α which is normal temperature sensitivity, so as to be installed in the lens holder. In such a case, at a high temperature, coma aberration is not sufficiently corrected by the amount of (β1′−β1). Further, at a low temperature, coma aberration is excessively corrected by amount of (β1″−β1). In the case where the excess or deficiency becomes large, the recording and reproducing characteristic of the optical disc deteriorates.

As shown in FIG. 6A, the optical pickup 3 according to the present embodiment is arranged in the lens holder 52 so that the optical axis of the light beam guided to the first objective lens 33 by the first light guiding optical system 28 coincides with the optical axis of the first objective lens 33. That is, the first objective lens 33 is arranged with respect to the lens holder 52 without inclination. Accordingly, without influences of the lens tilt coma aberration sensitivity according to the above described temperature change, changes in the coma aberration due to the temperature change may be prevented. Next, in a configuration shown in FIG. 6A, a reducing method of the initial coma aberration reduced by inclining the objective lens as shown in FIG. 6B in the related art will be described in “4. Correction of initial coma aberration”.

4. Correction of Initial Coma Aberration

In the optical pickup 3, the correction of the initial coma aberration is performed by adjusting a relative inclination of the optical disc 2 and the optical pickup 3 when forming the optical disc apparatus 1. Specifically, the optical pickup 3 performs skew adjustment in a skew direction Sk of the optical pickup 3 as shown in FIG. 7 when forming the optical disc apparatus 1, to adjust the relative inclination of the optical disc 2 and the optical pickup 3 and to restrict the initial coma aberration. Here, the skew direction Sk corresponds to the above described tilt direction Tir and is inclined in an axial rotational direction which centers around the tangential direction Tz, similarly to the tilt direction Tir. That is, the coma aberration is generated when the optical disc 2 and the optical pickup 3 are relatively inclined, and there is a certain relation between the inclination angle and the amount of the coma aberration. The adjustment of the skew angle in the tilt direction of the optical pickup 3 will be described in “5. Relative angle adjustment of optical pickup with respect to optical disc”.

Further, in order to adjust such a relative inclination, the disc mounting unit on which the optical disc 2 is mounted to be skew-adjusted. That is, a disc installation reference surface 67a of the disc mounting unit 67 may be inclined with respect to the optical pickup 3. In such a case, the optical pickup 3 and the optical disc which is installed in the disc mounting unit 67 are relatively inclined at such an angle that the disc mounting unit is inclined to optimally correct the coma aberration.

Here, the processes that the relative inclination of the optical disc 2 and the optical pickup 3 is adjusted and the initial coma aberration is corrected will be described in detail with reference to FIG. 11, in comparison with the above described FIG. 10. A ratio of the amount of generated coma aberration with respect to the relative inclination is referred to as disc tilt sensitivity. Here, FIGS. 10 and 11 illustrate the amount of coma aberration after spherical aberration correction in the case where the thickness of a cover layer of the first optical disc t1 is 100 μm. Specifically, FIG. 10 illustrates lens tilt com aberration sensitivity, and FIG. 11 illustrates disc tilt com aberration sensitivity.

The coma aberration generated by optical components included in the optical pickup 3 or assembly errors of the components is represented as Y as described above. In this case, the amount of lens tilt α is set to zero, and then the following adjustment is performed when the optical pickup is assembled. That is, the optical pickup 3 is inclined in the radial tilt direction Tir, in a direction in which the coma aberration is offset by the amount of disc tilt δ satisfying Y=β2 using disc tilt sensitivity β2/δ indicated by a solid line LD in FIG. 11. In this respect, as described above, the optical disc installation reference surface may be inclined so that the optical disc is inclined. In such a case, since α≅0, (β1′−β1)≅0 and (β1″−β1)≅0. Generally, the disc tilt sensitivity is approximately constant according to temperature. By employing a method as shown in FIG. 7, the coma aberration is not significantly changed even though there is a temperature change, and thus, the recording and reproducing characteristic with respect to the optical disc may be preferably maintained.

However, as shown in FIG. 7, the optical pickup 3 is tilt-adjusted in the range of about ±0.5° so that the optical pickup 3 is relatively inclined with respect to the optical disc 2 at such an angle that the initial coma aberration with respect to the first optical disc due to the first objective lens 33 is optimally corrected. Specifically, the optical pickup 3 is installed so that the coma aberration is optimally corrected when the angle between a central axis of the first objective lens 33 and the optical disc installation reference surface is in the range of about 90±0.5°. Hereinafter, the process that the coma aberration is optimally corrected in the range of about ±0.5 will be described.

In the first objective lens corresponding to the first optical disc having a first wavelength λ1 and a thickness t1 of the cover layer t1, a case that the coma aberration of the optical pickup 3 is 0.05λrms and respective tilt sensitivities are as follows is described as an example. As an another condition, high temperature lens tilt sensitivity is 0.01λrms/°, normal temperature lens tilt sensitivity is 0.08λrms/°, low temperature lens tilt sensitivity is 0.15λrms/° and disc tilt sensitivity is 0.10λrms/°. In the related art, as shown in FIG. 6B, in the normal temperature, the lens is inclined by 0.05/0.08=0.625° to correct the coma aberration. In this case, since coma aberration of about 0.625×0.01=0.006λrms is corrected in a high temperature, a deficiency of the coma aberration correction of 0.044λrms is generated. In addition, since coma aberration of about 0.625×0.15=0.094λrms is corrected in a low temperature, an excess of the coma aberration correction of 0.044λrms is generated.

Here, if an inclination 0±0.35° of the optical disc which is standardized is changed into disc tilt sensitivity, it becomes 0.035λrms. In consideration of influences of the optical disc with respect to a general Marechal limit 0.07λrms, it is necessary to reduce the aberration of the optical pickup to half or less of the Marechal limit. However, since aberration of more than 60% is generated, disc reading capability may deteriorate exceeding the Marechal limit. In the case of deterioration of the optical disc reading capability, it is conceivable to dynamically correct coma aberration using the objective lens driving unit 51 which is the tilt correction mechanism. However, since the lens tilt sensitivity is low in a high temperature, it is difficult to correct the coma aberration even though the tilt correction mechanism is dynamically operated.

In the optical pickup 3, as shown in FIG. 6A, without inclining the first objective lens 33, a relative angle between the optical disc installation reference surface of the optical disc as shown in FIG. 7 and the optical pickup is inclined by the amount of coma aberration/disc tilt sensitivity of 0.05/0.1=0.5°. With such a configuration, the coma aberration of the optical pickup 3 is corrected.

In this case, in the second objective lens corresponding to the second optical disc having a second wavelength λ2 and the thickness t2 of a cover layer, a relation of the coma aberration of the optical pickup 3 with respect to coma aberration generated in a relative inclination of the optical disc installation reference surface and the optical pickup may not coincide with each other. In this case, the optical disc reading capability may be preferably maintained under optimal reproducing conditions, using the objective lens driving unit 51 which is the tilt correction mechanism.

5. Relative Angle Adjustment with Respect to Optical Disc

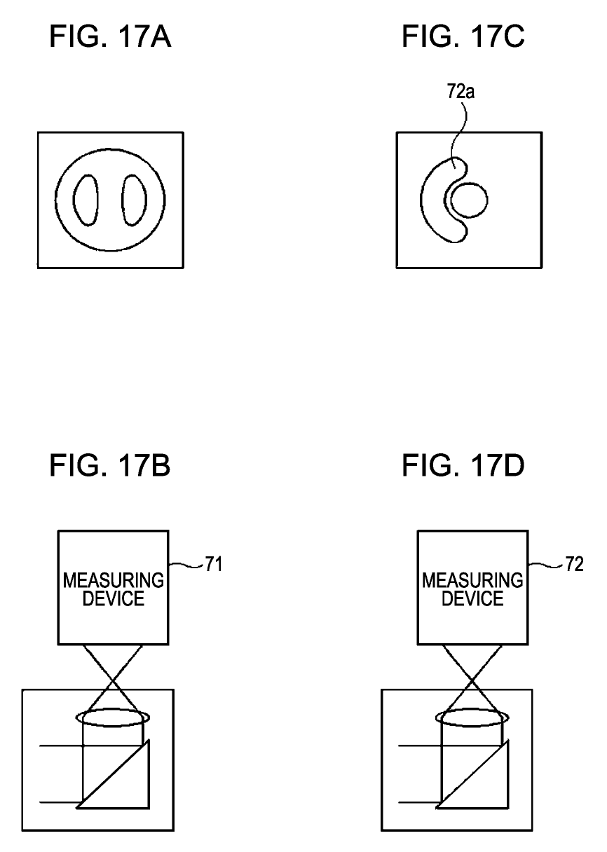

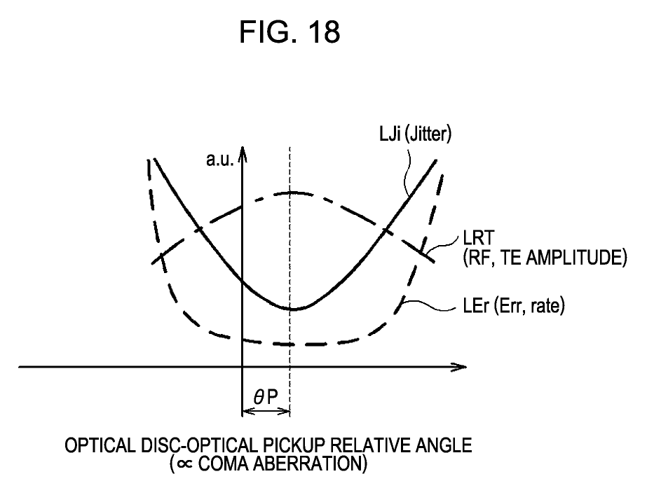

Next, a method for adjusting the relative angle between the optical pickup and the optical disc will be described with reference to FIG. 12. Specifically, as shown in FIG. 12, in the optical disc apparatus 1 are installed the main shaft 62 and the sub shaft 63 as guide shafts which are inserted into the pickup base 50 on which the optical pickup 3 is installed and support movement of the pickup base 50 in the radial direction of the optical disc. Further, the optical disc apparatus 1 includes skew adjusting mechanisms 64 which are installed in opposite end parts of each of the main shaft 62 and the sub shaft 63. Each skew adjusting mechanism 64 includes, for example, a spring 65 which supports each of the main shaft 62 and the sub shaft 63 from an upper side of the focus direction F, and an adjusting screw 66 which is in contact with a lower part of each of the main shaft 62 and the sub shaft 63 and presses each of the guide shafts to adjust the vertical height of each of the main shaft 62 and the sub shaft 63. According to the height of the opposite sides of each of the main shaft 62 and the sub shaft 63 is adjusted by the skew adjusting mechanism 64, the optical pickup 3 is installed in the optical disc apparatus 1 in a predetermined installation height while adjusting a tilt angle of the radial tilt direction. For example, while viewing output of the optical pickup 3, the adjusting screw of the skew adjusting mechanism 64 is turned to adjust the height of the opposite sides of each of the main shaft 62 and the sub shaft 63 as the guide shafts, and thus, the optical pickup 3 is adjusted. A method for determining the amount of skew is not limited thereto, which will be described with reference to FIGS. 17 and 18. That is, according to adjustment of the skew angle of the radial tilt direction by means of the skew adjusting mechanism 64, the optical pickup 3 is installed in the optical disc apparatus 1 in the above described state that the initial coma aberration is restricted. The configuration of the skew adjusting mechanism is not limited to the above described examples, and any configuration which is capable of skew adjustment of the optical pickup 3 may be employed. In addition, a configuration that the disc mounting unit on which the optical disc is mounted may be skew-adjusted may be employed. That is, the disc installation reference surface 67a of the disc mounting unit 67 may be inclined with respect to the optical pickup 3.

6. Functions and Effects of Optical Pickup

As described above, the optical pickup 3 according to the present embodiment corresponds to the high density recording such as BD, and is installed in the lens holder 52 in a state that the optical axis of the plastic first objective lens 33 coincides with the optical axis of the first light guiding optical system 28. Here, the optical axis of the first light guiding optical system 28 refers to the optical axis of the light beam which is guided by the first light guiding optical system 28 and is incident to the first objective lens 33. Further, the optical pickup 3 is adjusted to be inclined to correct the initial coma aberration of the first objective lens 33 with respect to the disc installation reference surface 67a. In this way, the optical pickup 3 is configured in consideration of temperature characteristics of the lens tilt coma aberration sensitivity of the first objective lens 33. With such a configuration, the optical pickup 3 may reduce variation of the coma aberration when there is change in environment temperature, that is, may perform recording and reproducing in a state that the coma aberration is reduced. Accordingly, the optical pickup 3 improves productivity and weight saving by using the plastic first objective lens 33, and realizes preferable recording and reproducing characteristics even though there is the environment temperature change with the configuration in consideration of the variation of the lens tilt coma aberration sensitivity.

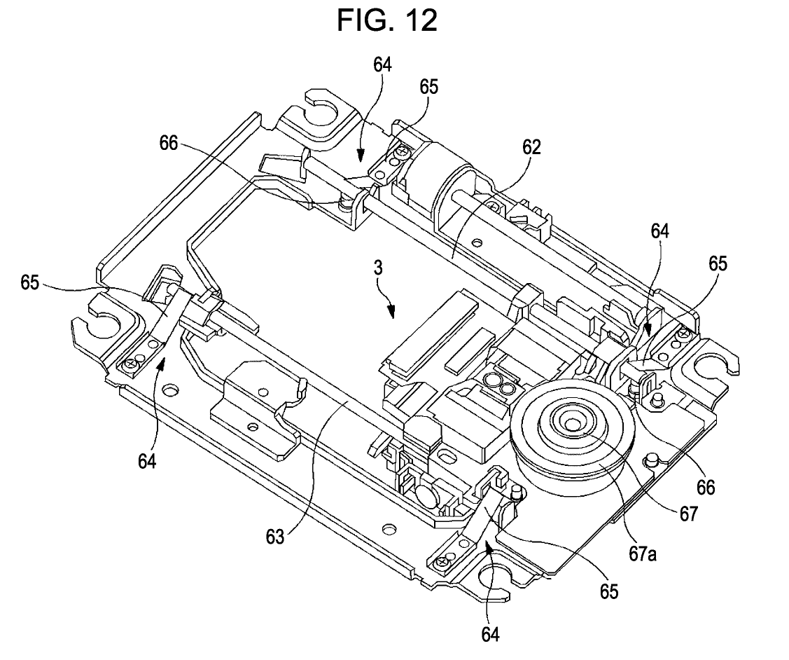

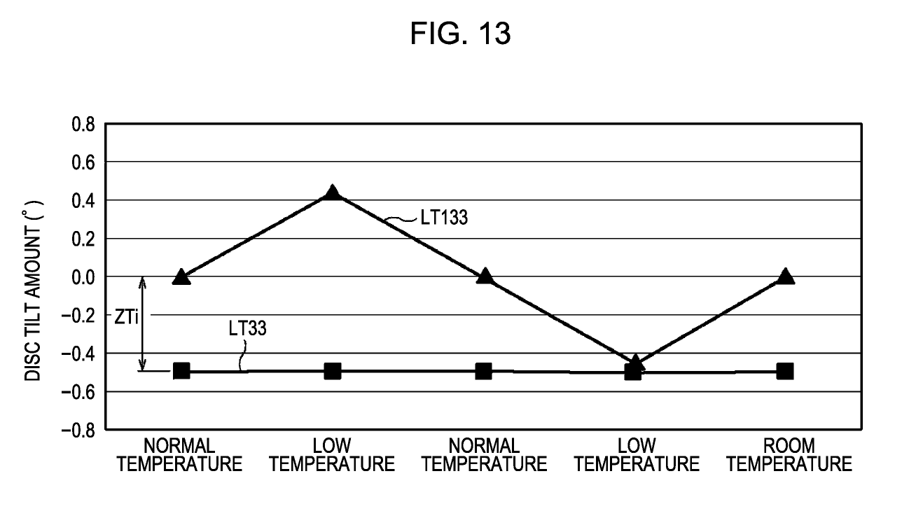

With such a configuration, a case that the variation of the coma aberration is reduced will be described with reference to FIG. 13. FIG. 13 is a diagram illustrating change in the amount of disc tilt according to temperature change of the first objective lens 33 having the configuration as described with reference to FIG. 6A and the objective lens 133 as described with reference to FIG. 6B as the comparative example. The transverse axis represents the temperature change and the longitudinal axis represents a value obtained by converting a residual amount of the coma aberration into the amount of the disc tilt. In other words, the amount of the disc tilt which offsets the residual coma aberration is indicated by the longitudinal axis. A reference LT133 represents the tilt change in the case of the comparative example, and the tilt change according to temperature is large in such a comparative example. This means that the tilt correction has to be more significantly performed at a high temperature, which may exceed a necessary tilt angle according to the configuration of the objective lens driving unit, in the configuration of the comparative example. Further, this means that the tilt correction angle may be small in a low temperature, but the sensitivity becomes high and thus a minute adjustment may not be performed, or quite significant coma aberration may be generated in the case where the angle is changed due to impacts or the like. In addition, a reference LT33 in the figure represents tilt change in the case of the configuration as in the first objective lens 33 for forming the above described optical pickup 3, and represents that the tilt change is small according to temperature in the present embodiment. This means that change in the tilt sensitivity is small in the present embodiment. Here, as indicated by a reference ZTi in the figure, there is a deviation from 0°, but as shown in FIG. 7, the amount of the deviation may be corrected by adjusting the relative angle between the optical pickup 3 and the optical disc installation reference surface. In other words, with the configuration as shown in FIGS. 6A and 7, the remaining amount of the coma aberration in a normal temperature may become small and variation of the coma aberration due to the temperature change may be reduced.

That is, the optical pickup 3 is arranged so that the optical beam entering into the first objective lens 33 parallels with an axis connecting centers of the optical surface of light entering side and light emitting side which form the first objective lens 33, and maintains the relation in the operational state. The optical pickup 3 may prevent change in the coma aberration under the environment temperature. Accordingly, the optical pickup 3 may prevent deterioration of the recording and reproducing capability in the high and low temperature environments when the first objective lens 33 corresponding to the high density recording optical disc is used.

Further, the optical pickup 3 does not use the objective lens driving unit 51 which is the tilt correction mechanism even though the environment temperature is changed when reproducing the first optical disc, and drives the tilt correction mechanism in order to obtain an optimal reproducing environment when reproducing the second optical disc to incline the lens holder 52.

In addition, the first objective lens 33 of the optical pickup 3 satisfies a predetermined sensitivity under the condition that environment temperature is 0° C. to 70° C., the thickness of a protection layer of the first optical disc is 70 μm to 105 μm, and a wavelength λ1 of the light beam is 398 nm to 414 nm. In such a condition, in the state that the generated spherical aberration is corrected by moving the first collimating lens 36, the first objective lens 33 is inclined and thus has a characteristic in the range of a ratio of the coma aberration generated in the light beam having a corresponding first wavelength λ1. Specifically, under such a condition, lens tilt coma aberration sensitivity which is the ratio of the coma aberration corresponding to the lens tilt satisfies 0 to 0.3λrms/°. This is because manufacturing errors or the like generated when making the optical axis of the light beam and the optical axis of the lens coincide with each other may be ignored, in the case of a lens which has lens tilt coma aberration sensitivity exceeding 0.3λrms/° under the condition. Further, this is also because such a lens is configured so that a relative change between the optical axis of the light beam and the optical axis of the lens due to a temporal change or an environmental change may be ignored. In addition, this is also because such a lens is configured so that a relative change between the optical axis of the light beam and the optical axis of the lens due to change in a posture of the lens holder when the lens holder is displaced in the focus direction and in the tracking direction. In this way, under the above described condition, it is preferable that the lens tilt coma aberration sensitivity is 0 to 0.3λrms/°. Further, the objective lens having the lens tilt coma aberration sensitivity in the range of 0 to 0.3λrms/° under the above described condition may obtain the above described effects by the configuration as described with reference to FIGS. 6A and 7.

7. Direction of Coma Aberration of Objective Lens and Installation Direction

Next, in the optical pickup 3, advantages in the case where coma aberrations of the first and second objective lenses 33 and 34 are directed in the radial direction as described with reference to FIG. 9 will be described. As described above, the coma aberration generated in the optical pickup 3 includes the coma aberration of the objective lens itself, the coma aberration of a collimating lens or an another optical component, and the coma aberration by assembly errors of the optical components. In addition, in the objective lens made of plastic, it is necessary to take into consideration coma aberration generated in the case where there is a temperature gradient in optical beam passing regions. That is, when there is a temperature gradient in the passing regions, a refractive index varies for every region, and thus, coma aberration is generated. Further, the temperature gradient is generated due to heat generation of a coil for driving the lens actuator and windage loss generated by rotation of the optical disc.

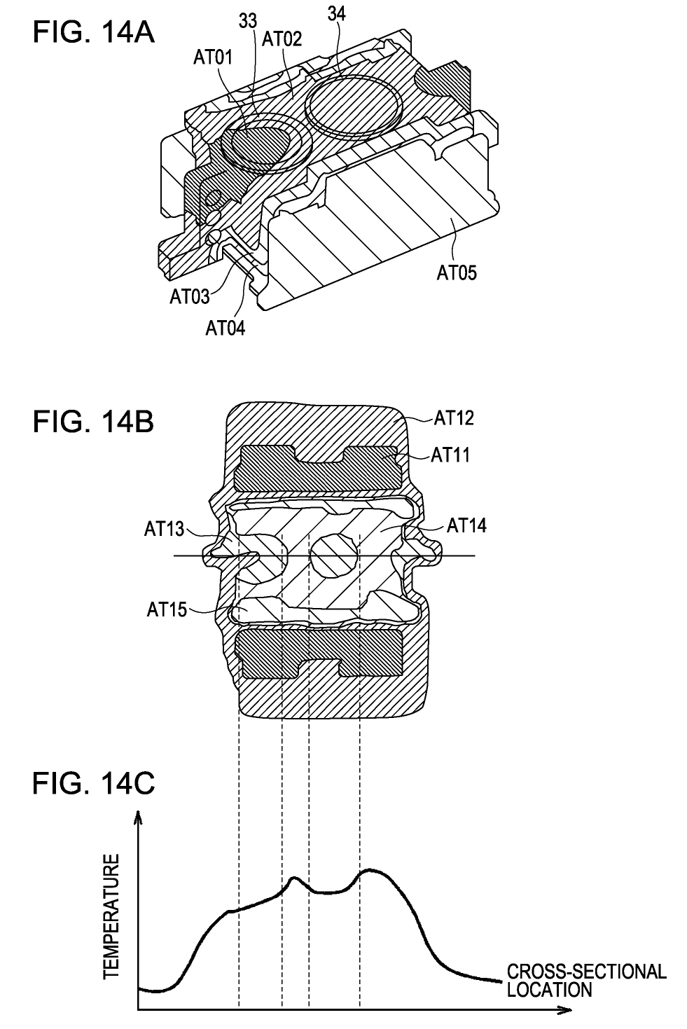

Here, the temperature gradient generated in the light beam passing region of the first and second objective lenses 33 and 34 included in the optical pickup 3 will be described with reference to FIGS. 14A to 14C. Referring to FIGS. 14A and 14B, asymmetric temperature distribution is generated in the first objective lens 33 corresponding to, for example, BD or the like, in comparison with the second objective lens 34 corresponding to, for example, DVD or the like. In the case where the asymmetric temperature distribution is generated in the objective lenses, refractive index is changed in every distribution location. In the case where there is such a distribution as shown in FIGS. 14A and 14B, coma aberration is generated in the radial direction. In addition, in the case where the coil is arranged as shown in FIG. 3, the temperature distribution as shown in FIGS. 14A and 14B is generated. In FIG. 14A, references AT01 to AT05 respectively represent regions of predetermined temperature ranges. Here, the reference AT05 represents the highest temperature, the references AT04, AT03 and AT02 respectively represent gradually decreasing temperatures, and the reference AT01 represents the lowest temperature. In FIG. 14B, references AT11 to AT15 respectively represent regions of predetermined temperature ranges. Here, the reference AT15 represents the highest temperature, the references AT14, AT13 and AT12 respectively represent gradually decreasing temperatures, and the reference AT11 represents the lowest temperature. FIG. 14C illustrates a section of objective lens temperature distribution in a radial direction. In FIG. 14C, the transverse axis represents a sectional position, the longitudinal axis represents temperature. In FIG. 14C, temperature distribution having a steep temperature difference in the sectional position corresponding to the first objective lens 33.

The temperature differences generated in the objective lens are determined by the following four factors. The first factor is the shape of the lens holder which holds the objective lens. The second factor is the relative location relation between each coil and the objective lens. The third factor is the amount of electric current flowing in the coil. The fourth factor is the windage loss which may be generated by the rotation of the optical disc. Here, since the third and fourth factors are significantly changed according to their operational states, the amount of generation of coma aberration according to the temperature differences of the objective lens may not have a constant value.

However, a generation direction of the coma aberration is mainly determined by the first and second factors. Accordingly, the relative angle between the optical disc installation reference surface of the spindle motor and a reference surface of the main shaft and the sub shaft of the optical pickup may be risen by the amount of average electric current empirically presumed from the third and fourth factors and the amount of coma aberration calculated from the windage loss. Thus, influences of the coma aberration according to the lens temperature may be reduced.

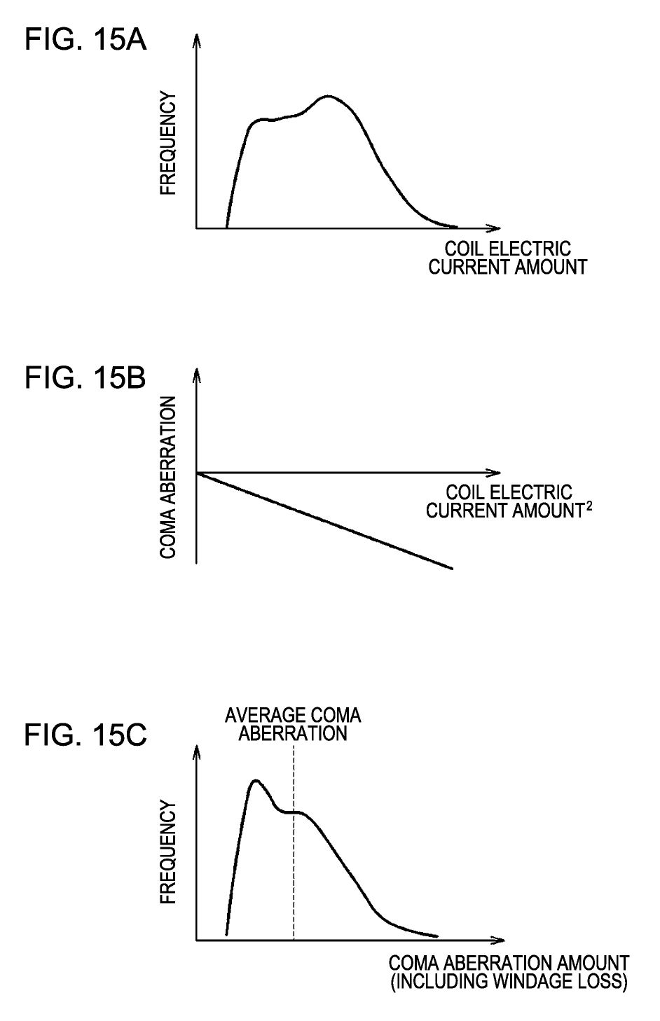

This will be described with reference to FIGS. 15A to 15C. FIGS. 15A to 15C illustrates coma aberration distribution according to the relation between the amount of coil electric current and the coma aberration. FIG. 15A illustrates the coil current amount indicated by the transverse axis and frequency distribution thereof indicated by the longitudinal axis. FIG. 15B illustrates the relation between the coil current amount and the coma aberration, where the transverse axis indicates a square value of the coil current amount and the longitudinal axis indicates the coma aberration. The square value of the coil current amount is proportional to the amount of generated heat and the coma aberration is proportional to the disc tilt. FIG. 15C illustrates distribution obtained from the relation between FIG. 15A and FIG. 15B, where the transverse axis indicates the coma aberration amount including windage loss and the longitudinal axis indicates frequency thereof. A dashed line in the figure indicates the amount of average coma aberration.

The optical pickup 3 according to the present embodiment has a characteristic that the optical pickup 3 is installed in the lens holder 52 so that the coma aberration of the first and second objective lenses 33 and 34 is directed in the same direction and in the radial direction. With such a configuration, as shown in FIG. 7, due to the relative inclination in a direction 8P in which an initial coma aberration of the first objective lens 33 is reduced, an initial coma aberration of the second objective lens 34 may be also reduced to some extent. That is, in the state that the tilt angle as described with reference to FIG. 8 is reduced in the case where the second objective lens 34 is used, preferable recording and/or reproducing characteristics are realized.

Further, the optical pickup 3 has a characteristic that the direction of the coma aberration due to the temperature difference of the first and second objective lenses 33 and 34 is set in an inner and outer circumference direction (radial direction) of the optical disc. Specifically, the first and second objective lenses 33 and 34 are arranged in the radial direction, and the coils are arranged in opposite sides of tangential directions of the first and second objective lenses 33 and 34. With such a configuration, the direction of the coma aberration due to the temperature difference of the first and second objective lenses 33 and 34 may be set as the radial direction. Accordingly, the optical pickup 3 may offset the coma aberration due to the temperature difference on average, to thereby reduce an influence thereof. In other words, the relative angle between the optical pickup and the optical disc is determined to be offset, so as to predict coma aberration generated by the amount of generated heat or temperature distribution in the proximity of the objective lens in a real operation state and to most remarkably reduce the coma aberration in such a usage state. Thus, the optical pickup 3 may prevent deterioration of the recording and/or reproducing characteristics due to a heat source such as a coil in the proximity of the lens when the first objective lens 33 corresponding to the high density recording optical disc is used. Further, the optical pickup 3 has such a configuration and the above described configuration that the coma aberration of the objective lenses is the same in the inner and outer circumference direction. Thus, the optical pickup 3 may correct the coma aberration by the relative angle adjustment as shown in FIG. 7 with respect to the first objective lens 33, and may correct the coma aberration by the tilt adjustment by means of the objective lens driving unit 51 shown in FIG. 8 with respect to the second objective lens 34.

In addition, the optical pickup 3 has a characteristic that the light emitting unit for the second wavelength λ2 and the light emitting unit for the third wavelength λ3 in the second light source 32 are arranged in parallel in a direction corresponding to the direction of the coma aberration of the second objective lens 34. Specifically, the light emitting unit for the second wavelength which is used for a DVD or the like is arranged on the optical axis of the second optical system, and the light emitting unit for the third wavelength which is used for a CD or the like is arranged off the optical axis of the second optical system. Further, with respect to the light emitting unit in which such a light emitting point is arranged in the off-axis way, a light beams enters into the second objective lens 34 in a inclined manner to arrange a direction of the generated off-axis coma aberration toward the optical disc inner and outer circumference direction (radial direction). In other words, when forming the second light source 32 as a two-wavelength laser for the DVD or CD, the light emitting point used in the off-axis arrangement is arranged in view of the following point. That is, the off-axis coma aberration is arranged in a direction in which the off-axis coma aberration is offset by coma aberration generated by a skew adjustment direction of the relative angle of the optical pickup in the first objective lens 33. Thus, the optical pickup 3 may reduce the coma aberration due to the influence of the off-axis arrangement by the adjustment as shown in FIG. 7, and may correct the coma aberration by the tilt adjustment by means of the objective lens driving unit 51 as shown in FIG. 8, in the case where the third wavelength and the second objective lens 34 are used. The optical pickup 3 may simultaneously correct influences of the off-axis coma aberration in the optical path which is arranged in the off-axis way, as well as the above described effects, with such a configuration that the direction of the coma aberration of the objective lens itself, the direction of the coma aberration by the temperature change, and the direction of the off-axis coma aberration coincide with each other in the radial direction. That is, the optical pickup 3 skew-adjusts the optical pickup 3 in order to perform an optimization with respect to the first objective lens 33, to thereby reduce coma aberration generated as the influences due to the off-axis arrangement of the respective light emitting points for the second and third wavelengths of the second light source 32.

This will be further described with respect to FIGS. 16A and 16B. As shown in FIG. 16A, the first objective lens 33 and the second objective lens 34 may be exemplified as aberrations of D1 to D5. In the optical pickup 3, a direction of each aberration is arranged in a radial direction. That is, firstly, the coma aberration D1 is generated when the light beam of the first wavelength λ1 passes through the first objective lens 33. The coma aberration D2 is a coma aberration average value (herein, referred to as “electric current coma aberration”) generated by the lens temperature difference in the first objective lens 33. The coma aberration D3 is generated when the light beam of the second wavelength λ2 passes through the second objective lens 34. The coma aberration D4 is generated when the light beam of the third wavelength λ3 passes through the second objective lens 34. The coma aberration D5 is an off-axis coma aberration which is generated in the light beams of the third wavelength when the light emitting unit 34b for the third wavelength of the second light source 32 in the second optical system is arranged in the off-axis way.

In the optical pickup 3, the light emitting unit 34b for the third wavelength of the second light source 32 is arranged to align directions of the coma aberrations D2 and D5, to thereby obtain the following effects. That is, with such a configuration, the coma aberration generated in the light beam of the first wavelength and the coma aberration generated in the light beam of the third wavelength become relatively small. Such a configuration indicates that the relative disc tilt of the case that the first wavelength is used and the case that the third wavelength is used becomes small. The optical pickup 3 has the following effects by such a configuration and a configuration that optimal relative angle adjustment is performed with respect to the first objective lens 33 as described with reference to FIG. 7. That is, as shown in FIG. 16B, in the optical pickup 3, the relative angle θP between the disc installation reference surface and the optical pickup is adjusted to remove the coma aberrations D1 and D2. Accordingly, the optical pickup 3 may reduce the amount of tilt residual which is generated in the light beam of the third wavelength of the second objective lens 34. In other words, the optical pickup 3 may reduce the tilt angle by the objective lens driving unit 51 in the case where the light beam of the third wavelength is used.

8. Manufacturing Method of Optical Pickup

Next, a manufacturing method of the optical pickup 3 according to an embodiment of the invention will be described.

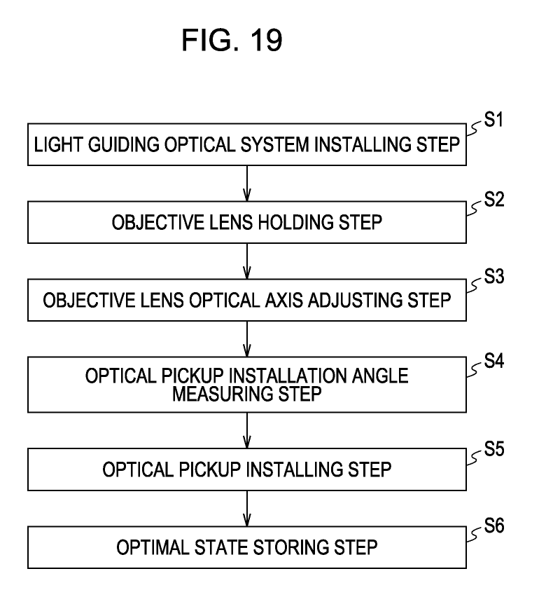

The manufacturing method of the optical pickup 3 includes steps S1 to S6 as shown in FIG. 19.

In step S1, the first and second light guiding optical systems 28 and 29 are installed in the pickup base 50 which is a base member. In other words, in step S1, optical components for forming the first and second light guiding optical systems 28 and 29 are installed.

Specifically, in step S1, the first and second light sources 31 and 32 on the first and second raising mirrors 41 and 42 are adjusted and arranged so that optical axes of the light beams of the first and second wavelengths are vertically raised with respect to the main shaft and sub shaft reference surface of the optical pickup 3. Further, other optical components are adjusted and arranged from the same point of view. The main shaft and sub shaft reference surface is a planar surface which includes central lines of the main shaft 62 and the sub shaft 63 which guide the optical pickup 3.

In step S1, the light emitting point for the first wavelength of the first light source 31 is adjusted to be located on the optical axis of the first light guiding optical system 28. The light emitting point for the first wavelength of the first light source 31 is adjusted so that the light beam reflected by the first raising mirror 41 after passing through the optical axes of the respective optical components is located to be vertically raised with respect to the main shaft and sub shaft reference surface. Further, the light emitting point 34a for the second wavelength of the second light source 32 is adjusted to be located on the optical axis of the second light guiding optical system 29. Further, the light emitting point 34a for the second wavelength of the second light source 32 is adjusted so that the light beam reflected by the second raising mirror 42 after passing through the optical axes of the respective optical components is located to be vertically raised with respect to the main shaft and sub shaft reference surface. However, the light emitting point 34b for the third wavelength of the second light source 32 is located in the off-axis way with respect to the light emitting point for the second wavelength which is located on the axis, but is adjusted to be located in a radial direction which is the direction of the coma aberration of the second objective lens 34 (see FIGS. 16A and 16B). Further, other components for forming the first and second light guiding optical systems 28 and 29 are arranged so that the light beams emitted from the first and second light sources 31 and 32 pass through the centers of the other components.

In step S2, the first and second objective lenses 33 and 34 are held in the lens holder 52 of the objective lens driving unit 51.

Specifically, in step S2, the first and second objective lenses 33 and 34 are arranged so that the directions of the respective coma aberrations coincide with each other in a radial direction, for example, in an outer direction, and are held in the lens holder 52 of the objective lens holder 51. Further, at this time, the optical axes of the first and second lenses 33 and 34 are installed as parallel as possible. Accordingly, as described later, the optical axis of the first objective lens 33 is adjusted so that the optical axis of the second objective lens 34 can also become a desired state.

In step S3, as shown in FIG. 6A, the objective lens driving unit 51 is installed in the optical pickup 3 so that the optical axis of the first objective lens 33 coincides with the optical axis of the first light guiding optical system 28. That is, the optical axis of the objective lens is adjusted.

In step S3, the support 53 which is the actuator holding unit is installed in the pickup base 50 of the optical pickup 3 to install the objective lens driving unit 51 in the optical pickup 3. When installing the objective lens driving unit 51, the tilt correction mechanism is in a turned off state. The objective lens driving unit 51 is adjusted so that the optical axis of the first objective lens 33 coincides with the optical axis of the light beam which is guided from the first light guiding optical system 28 in the state that the lens holder 52 which is the actuator operating unit is not displaced in the tilt direction with respect to the support 53. The state that the lens holder 52 is not displaced in the tilt direction refers to a location relation which becomes a reference of the lens holder 52 and the support 53 in the case where the first objective lens 33 is used. For example, such a state refers to the state that the lens holder 52 is displaced in the optical axis direction with respect to the state that the lens holder 52 is not displaced with respect to the support 53. Accordingly, the optical axis of the second objective lens 34 comes to nearly coincide with the optical axis of the second light guiding optical system 29, but the optical axis of the first objective lens 33 which performs the high density recording and reproducing is firstly adjusted to become an optimal state. Specifically, the optical axis of the first objective lens 33 is adjusted to be vertical with respect to the main shaft and sub shaft reference surface of the optical pickup 3. In other words, the optical axis is adjusted so that the lens outer circumference which has a surface perpendicular to the optical axis of the lens is in parallel with the main shaft and sub shaft reference surface.

In steps S2 and S3, the objective lenses are adjusted. In such steps, the first objective lens 33 is held in the lens holder 52 of the optical pickup 3 so that the optical axis of the light beam which is guided to the first objective lens 33 by the first light guiding optical system 28 approximately coincides with the optical axis of the first objective lens 33.

In step S4, the installation angle of the optical pickup is measured. Here, the installation angle refers to the installation angle for adjusting the relative angle between the optical pickup 3 and the optical disc installation reference surface, that is, the amount of skew. In step S4, an optimal value of the relative angle between the optical pickup 3 and the disc reference surface in the case where the first objective lens 33 is used is measured.

Here, a method for calculating the necessary amount of skew will be described with reference to FIGS. 17A to 17D. For example, in step S4, a measuring device 71 which includes an interferometer or a wave-front sensor shown in FIG. 17B is used for obtaining an output as shown in FIG. 17A. The measuring device 71 measures coma aberration (λrms) of the light beam which passes through the first objective lens 33 of the optical pickup 3 in which the first objective lens 33 is installed as described above. The measuring device 71 calculates an optimal relative angle from the coma aberration and disc tilt sensitivity thereof. Here, a relation that the optimal relative angle) (°) is coma aberration (λrms)/disc tilt sensitivity) (λrms/°) is obtained.

Further, another method for calculating the necessary amount of the skew will be described with reference to FIGS. 17C and 17D. In this method, a measuring device 72 capable of performing spot measurement shown in FIG. 17D is used for obtaining an output as shown in FIG. 17C. The measuring device 72 measures the shape of the spot of the light beam which passes through the first objective lens 33 while inclining the optical pickup 3 in which the first objective lens 33 is installed as described above, as shown in FIG. 17C. The measuring device 72 measures an angle that the intensity of a first ring 72a is balanced as the optimal relative angle.

Further, still another method for calculating the necessary amount of the skew will be described with reference to FIG. 18. In this method, an OPU evaluation device measures jitter or the like while changing the relative angle between the optical pickup and the optical disc installation reference surface. A relative angle in which the jitter is the smallest and optimal is calculated as the optimal relative angle θP. In the case shown in FIG. 18, a signal other than the jitter may be detected, for example, a relative angle in the case where amplitude of the RF signal or the tracking error signal becomes a maximum may be calculated as the optimal angle. Further, time when an error rate becomes small may be detected as the optimal angle.

In step S4, with any method, the optimal angle in the case where the first objective lens 33 is used is calculated. Further, an optimal angle in the case where the second objective lens 34 is used is measured and detected for step S6.

In step S5, the optical pickup is installed. In step S5, the skew adjustment mechanism 64 adjusts the height of the main shaft 62 and the sub shaft 63 which support the optical pickup 3 so that the relative angle between the disc installation reference surface 67a and the optical pickup 3 becomes the optimal angle calculated in step S4. The optical pickup 3 is installed in the optical disc apparatus 1 in the state of the optimal relative angle.

In steps S4 and S5, the installation angle of the optical pickup is adjusted. In such steps, the optical pickup 3 is adjusted so that the installation angle of the optical pickup becomes an optimal relative angle with respect to the optical disc. Here, the optical pickup 3 is adjusted to have the optimal relative angle in the case where the first objective lens is used. In this respect, the step S4 and the step S5 may be configured to be the same. In this case, specifically, for example, aberration of the optical pickup is directly measured while changing the relative angle between the optical pickup 3 and the disc reference surface, and then the optical pickup 3 is adjusted so that the aberration becomes optimal.

Step S6 is an optimal state calculation and storing step in which an optimal tilt angle when the second objective lens 34 is used is calculated and stored. In step S6, the measuring devices 71 and 72 or the like calculate the optimal tilt angle when the second objective lens 34 is used, on the basis of the measured result in step S4. That is, in step S4, the optimal relative angle of the optical pickup 3 when the first objective lens 33 is used and the optimal relative angle of the optical pickup 3 when the second objective lens 34 is used are calculated. The measuring devices 71 and 72 or the like calculate an optimal tilt angle θA shown in FIG. 8 when the second objective lens 34 is used, in the optical pickup 3 which is inclined in the relative angle θP as shown in FIG. 7, on the basis of the two optimal relative angles. The calculated optimal tilt angle θA is such a tilt angle that an initial coma aberration with respect to the second and third optical discs due to the second objective lens 34 is optimally corrected using the objective lens driving unit 51 which is the tilt correction mechanism. In this step, an internal memory 26 of the optical pickup 3 which is a storing unit stores the tilt angle θA. When performing the recording and reproducing, as shown in FIG. 8, the optical pickup 3 inclines the second objective lens 34 by the objective lens driving unit 51, on the basis of the tilt angle θA stored in the internal memory 26 in the case where the second objective lens 34 is used. Here, the optimal tilt angle of the second objective lens 34 calculated in step S4 is calculated, and the tilt angle θA is calculated on the basis of the optimal tilt angle, but this is not limitative but used as an example. That is, for example, in the optical pickup 3 which is installed as shown in FIG. 7, the tilt may be changed as shown in FIG. 8, and thus, an angle when the aberration of the light beam which is focused by the second objective lens 34 becomes the smallest may be set as the tilt angle θA. Here, information on the tilt angle θA is stored in the internal memory 26 in the optical pickup 3, but this is not limitative but used as an example. That is, as the storing unit which stores the tilt angle θA, a memory included in a system controller 7 of the optical disc apparatus 1 or a memory connected to the system controller 7 may be used. In this way, in the case where the optical pickup 3 does not have a memory, the optimal tilt angle θA calculated in step S4 is stored, for example, using a two-dimensional bar code or the like as a storing unit for information transmission. Specifically, the two-dimensional bar code or the like capable of optically reading information including the tilt angle θA is created by a manufacturing apparatus to be attached on a surface of a case of the optical pickup 3. When the optical pickup 3 is assembled in the optical disc apparatus 1, the bar code may be read by the manufacturing apparatus, to thereby store the information in the storing unit (memory) in the optical disc apparatus 1.

According to the above described optical pickup manufacturing method, it is possible to manufacture the optical pickup 3 having an effect that variation of coma aberration is reduced in temperature change in the case where the objective lens for the above described high density recording optical disc is made of plastic. The manufacturing method particularly include step S3, to thereby realize reduction of the variation of the coma aberration in temperature change in the case where the first objective lens 33 is used. Further, the manufacturing method particularly includes step S6, to thereby reduce the coma aberration with respect to the second and third optical discs using the second objective lens by the optical pickup in which the first objective lens 33 is optimized as described above.

9. Control Method of Optical Pickup

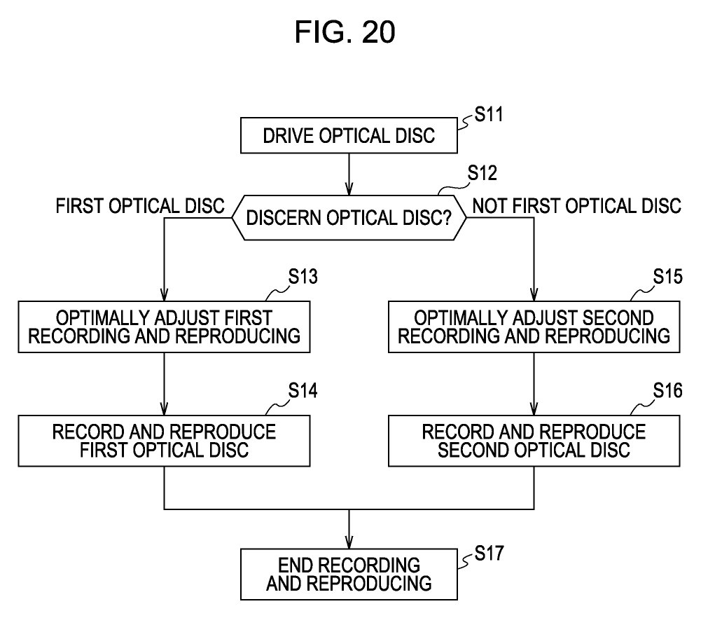

Next, a control method of the optical pickup 3 will be described with reference to FIG. 20. Specifically, the optical disc apparatus 1 having the above described optical pickup 3 performs a recording and reproducing method as shown in a flowchart in FIG. 20 and performs control of the optical pickup 3 in the recording and reproducing. The recording and reproducing method corresponds to steps S11 to S17.

In step S11, if an optical disc 2 is mounted in the disc mounting unit of the optical disc apparatus 1 and a starting button for the recording or reproducing is manipulated, the system controller 7 drives the laser control unit 21 so that the light beam is emitted from the first or the second light source 31 or 32. Further, in step S11, the system controller 7 drives the spindle motor 4 in the servo control unit 9 to rotate the optical disc 2 mounted in the disc mounting unit.

Next, in step S12, the optical pickup 3 and the disc type discerning unit 22 detects change in the amount of the reflected light from difference in surface reflectivity, shapes and appearances or the like, to thereby detect and discern the optical disc 2. According to the result of the optical disc discerning step, in the case where the light beam of the first wavelength is used, a tilt correction function of the objective lens driving unit 51 is not used, in the case where the light beam of the second and third wavelengths is used, the tilt correction function of the objective lens driving unit 51 is used. Further, in step S12, in the case where it is discerned that the mounted optical disc is the first optical disc 11, the procedure goes to step S13. In addition, in step S12, in the case where it is discerned that the mounted optical disc is not the first optical disc 11, the procedure goes to step S15. In the case that the mounted optical disc is not the first optical disc 11, the mounted optical disc corresponds to the second and third optical discs. In this respect, the mounted optical disc may correspond to any one of the second and third optical discs 12 and 13.

In step S13, the respective components of the optical pickup 3 are adjusted (first optimal adjustment) to perform the recording and reproducing with respect to the first optical disc using the first objective lens 33. In step S13, the control unit 27 performs control so that the light beam of the first wavelength is emitted from the first light source 31, with an intensity corresponding to recording or reproducing. Further, the control unit 27 controls the collimating lens driving unit 48 under the control of the system controller 7 to move the first collimating lens 36 to a predetermined location. At this time, the first collimating lens 36 is moved to a reference location according to the type of the optical disc 2 which is detected by the disc type discerning unit 22. In addition, the control unit 27 slightly moves the first collimating lens 36 in an optical axis direction by the collimating lens driving unit 48 to correct spherical aberration. Specifically, the control unit 27 moves the first collimating lens 36 in a direction in which a quality level of the RF signal detected by the photodetector 39 is enhanced, that is, in a direction in which the amount of jitter of an RF signal detected by the photodetector 39 becomes the smallest. In this step, the servo control unit 9 drives the objective lens driving unit 51 on the basis of the focus error signal, to move the first objective lens 33 in the focus direction, thereby performing the focus control. In this step, the control unit 27 does not use the tilt correction function of the objective lens driving unit 51. In other words, the objective lens driving unit 51 does not drive the lens holder 52 and the first objective lens 33 in the tilt direction. Then, the procedure goes to step S14.

In step S14, the control unit 27 begins recording or reproducing of an information signal with respect to the optical disc 2. At this time, the optical pickup 3 performs recording and reproducing of the information signal with respect to the first optical disc in the state that the tile correction mechanism is not used. Further, in this step, the servo control unit 9 drives the objective lens driving unit 51 on the basis of the tracking error signal, to move the first objective lens 33 in the tracking direction, thereby performing a tracking control. In the case where it is determined by the system controller 7 that the recording and reproducing operation is completed, the procedure goes to step S17.

In step S15, each component of the optical pickup 3 is adjusted (second optimal adjustment) to perform recording and reproducing with respect to the second or third optical disc using the second objective lens 34. Hereinafter, a case where the recording and reproducing is performed with respect to the second optical disc will be described. In the case where recording and reproducing is performed with respect to the third optical disc, optimization adjustment corresponding to the third optical disc is performed and the recording and reproducing is performed using the tilt correction mechanism, like a case as described later. In step S15, the control unit 27 performs control so that the light beam of the second wavelength is emitted from the light emitting unit for the second wavelength of the second light source 32, with an intensity corresponding to the recording or reproducing.

In step S15, for example, the control unit 27 drives the objective lens driving unit 51 on the basis of the optimal tilt angle shown in FIG. 8 which is stored in the internal memory 26, to drive the lens holder 52 and the second objective lens 34 in the tilt direction. The second objective lens 34 is inclined as shown in FIG. 8 in the state that the coma aberration is reduced as described above. In this step, the servo controller 9 drives the objective lens driving unit 51 on the basis of the focus error signal, to move the second objective lens 34 in the focus direction, thereby performing a focus control. The procedure goes to step S16.

In step S16, the optical pickup 3 begins recording or reproducing of an information signal with respect to the optical disc 2. At this time, the optical pickup 3 uses the objective lens driving unit 51 which is the tilt correction mechanism to perform the recording or reproducing of the information signal with respect to the second optical disc. Further, in the case where the tile correction is dynamically performed, the servo control unit 9 determines the amount of the lens tilt correction in order to reduce the coma aberration with respect to warpage of the optical disc 2, and drives the objective lens driving unit 51 to displace the second objective lens 34 in the tilt direction. Further, in this step, the servo controller 9 drives the objective lens driving unit 51 on the basis of the tracking error signal to move the second objective lens 34 in the tracking direction, thereby performing a tracking control. In the case where it is determined by the system controller 7 that the recording and reproducing operation is completed, the procedure goes to step S17.

In step S17, the laser control unit 21 stops the light beam emitting from the first or the second light sources 31 or 32, and the servo control unit 9 stops driving of the spindle motor 4.

According to the above described process shown in FIG. 20, according to the type of the optical disc, the recording and reproducing may be respectively performed in an optimal coma aberration, for every objective lens to be used, and thus, preferable recording and reproducing characteristics are realized.

That is, the optical pickup control method including steps S12 to S16 has a characteristic that it is determined whether the tilt correction mechanism of the objective lens driving unit 51 is used in the case where the first objective lens is used and in the case where the second objective lens is used. That is, in the case that the recording or reproducing is performed with respect to the first optical disc, the optical pickup 3 performs the recording or reproducing of the information signal with respect to the first optical disc in the state that the tilt correction mechanism is not used, as shown in FIG. 7. On the other hand, in the case where the recording or reproducing is performed with respect to the second and third optical discs, the optical pickup 3 performs the recording or reproducing of the information signal with respect to the second and third optical discs using the tilt correction mechanism, as shown in FIG. 8.

The above described optical pickup control method reduces coma aberration in the case where there is an environment temperature change by the optical pickup 3 using the plastic lens as the objective lens for high density recording, to thereby realize desirable recording and reproducing characteristics.

As described above, the optical pickup 3 according to the embodiments of the invention uses the objective lens made of plastic to improve productivity and weight saving, and reduces the coma aberration in the case where there is an environment temperature change to realize the desirable recording and reproducing characteristics. That is, the optical pickup 3 realizes the productivity or weight saving, and simultaneously realizes the desirable recording and reproducing characteristics.

In the above description, the optical pickup 3 having two objective lenses is described, but the embodiments of the present invention is not limited thereto, but may be applied to an optical pickup having only one objective lens.

10. Another Example of Optical Pickup (Second Embodiment)

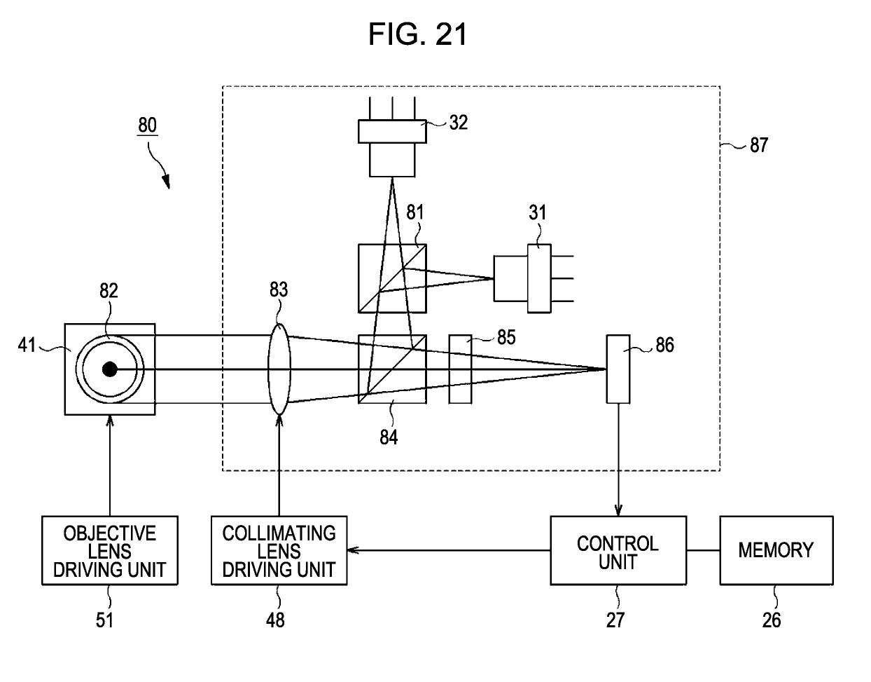

An optical pickup 80 having a single objective lens as another example of an optical pickup according to an embodiment of the invention will be described with respect to FIG. 21. Here, since a configuration of this embodiment other than the different number of the objective lens is the same as that of the above described optical pickup 3, like reference numbers are given to like elements and detailed description thereof may be omitted.

The optical pickup 80 includes a first light source 31, a second light source 32, and a beam splitter 81 which is a light path combining element which combines light paths of light beams emitted from the first and second light sources 31 and 32. Further, the optical pickup 80 includes, in place of the first objective lens 33 and the first collimating lens 36 as described above, an objective lens 82 and a collimating lens 83, which are configured to have the same functions as those of the first objective lens 33 and the collimating lens 36 to be common with respect to three wavelengths. In addition, the optical pickup 80 includes, in place of the polarized beam splitter 38, the multi lens 40 and the photodetector 39 as described above, a beam splitter 84, a multi lens 85 and a photodetector 86, which are configured to have the same functions as those of the polarized beam splitter 38, the multi lens 40 and the photodetector 39 to be common with respect to three wavelengths.

Similarly to the first collimating lens 36, a collimating lens driving unit 48 for driving the first collimating lens 36 in an optical axis direction is installed in the collimating lens 83. The collimating lens 83 and the collimating lens driving unit 48 may reduce spherical aberration generated according to temperature change, change of the thickness of a cover layer or the type of the disc, to thereby form an appropriate beam spot.

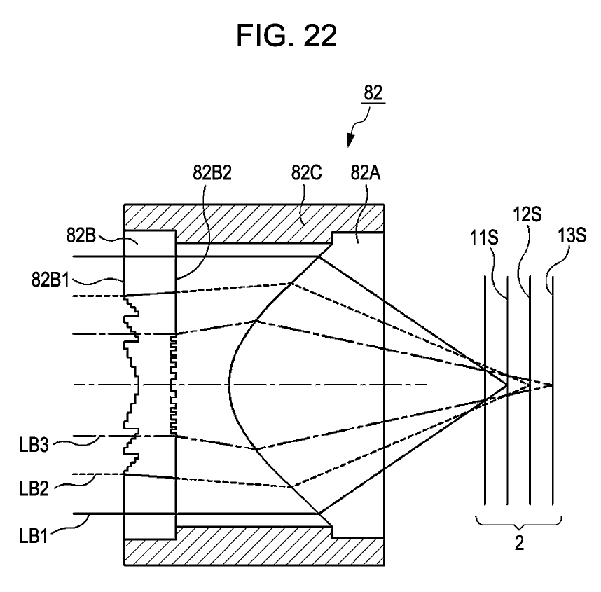

The objective lens 82 is an objective lens which focuses the light beam having different three wavelengths on signal recording surfaces of the first to third optical discs having different cover layers. The objective lens 82 includes, for example, as shown in FIG. 22, a first element 82A having a refraction function and a second element 82B having a diffraction function, and has triple-wavelength compatibility by combining the first and second elements 82A and 82B by a holder 82c. The objective lens 82, for example, appropriately focuses the light beam of a first wavelength on the signal recording surface 11s of the first optical disc by means of the refraction function of the first element 82A in the state that diffracting units 82B1 and 82B2 which are installed in the second element 82B are not diffracted with respect to a first wavelength LB1. The objective lens 82, for example, is configured so that the diffracting unit 82B1 installed in light incident surface of the second element 82B performs a predetermined diffraction with respect to a second wavelength LB2. The objective lens 82 appropriately focuses the light beam of the second wavelength on a signal recording surface 12s of the second optical disc by the predetermined diffraction and a refraction operation of the first element 82A. Further, the objective lens 82 is configured so that the diffracting unit 82B2 installed in a light exiting surface of the second element 82B performs the predetermined diffraction with respect to the third wavelength. The objective lens 82 appropriately focuses a light beam LB3 of the third wavelength on a signal recording surface 13s of the third optical disc by the refraction operation of the first element 82A. Here, the diffraction operation due to the second element 82B is not limited thereto, and the predetermined diffraction operation may be performed with respect to the first wavelength. Further, the diffracting unit installed in the second element 82B has, for example, a diffraction structure of a zona orbicularis shape in each of a plurality of regions, and may be configured so that the predetermined diffraction operation is performed in the light beam of each wavelength in every region. The objective lens realizes the triple-wavelength compatibility by the diffraction function of the second element 82B and the refraction function of the first element 82A. The objective lens having the triple-wavelength compatibility is not limited to the above described two-grouped configuration, for example, the diffracting unit having the above described diffraction function may be installed to be overlapped on a surface of the lens of a non-spherical surface shape having the refraction function.

The objective lens 82 is made of plastic, and is held to move by the objective lens driving unit 51, similarly to the above described first objective lens 33. The objective lens 82 is displaced by the objective lens driving unit 51 on the basis of a tracking error signal and a focus error signal generated by a returning light from the optical disc 2 which is detected by the photodetector 86. The objective lens 82 makes the light beams from first to third light emitting units follow a recording track which is formed in the recording surface of a corresponding optical disc. The objective lens driving unit 51 which is installed in the optical pickup 80 does not perform inclination of the objective lens 82 in a tilt direction when performing recording or reproducing with respect to the first optical disc. In other words, when performing the recording and reproducing with respect to the first optical disc, a tilt correction mechanism is not used, and even though temperature environment of the objective lens and the peripheral components thereof is changed, a current state thereof is maintained.

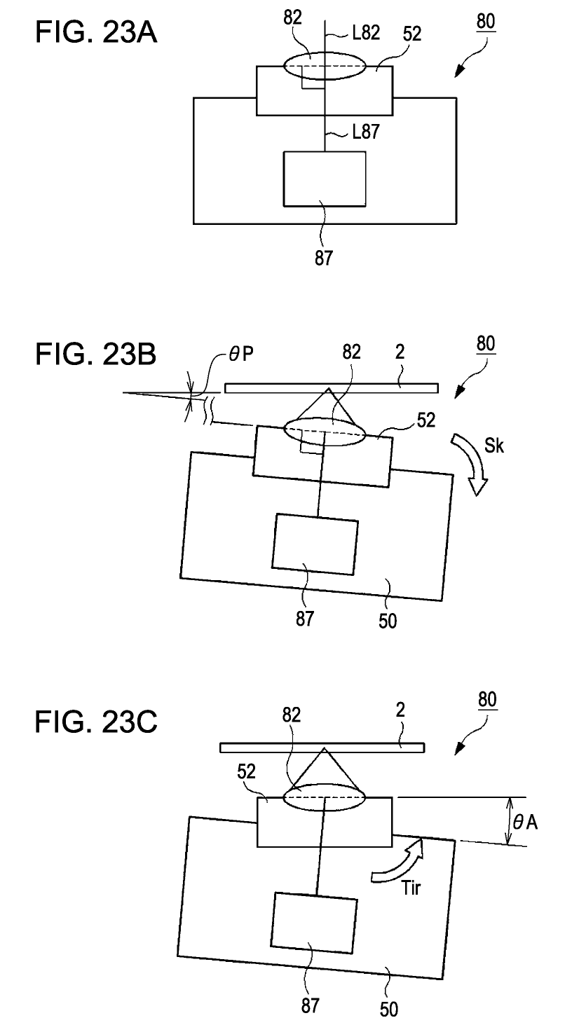

On the other hand, when performing the recording and reproducing with respect to the second and third optical discs, the objective lens driving unit 51 serves as the tilt correction mechanism, similarly to the above described second objective lens 34. That is, in the case where the light beam of the second and third wavelengths is incident, the objective lens driving unit 51 inclines the objective lens 82 in the corresponding tilt direction, as shown in FIG. 23C by a predetermined optimal angle θA so that coma aberration is most remarkably reduced. In other words, when performing the recording and reproducing with respect to the second and third optical discs, the tilt correction mechanism is used, and thus, optimal recording environment and reproducing environments may be obtained. In addition, the tilt driving in the case where the second and third optical discs are used may be static or dynamic.

As described above, the objective lens 82 capable of being inclined in the tilt direction in the case where the second and third wavelengths are used has the following effects in a configuration that a compatible objective lens having compatibility in a plurality of wavelengths is installed. Such a configuration may allow the objective lens 82 in the case where the first wavelength is used as shown in FIG. 23B to be installed in an optimal state. That is, in the compatible objective lens, there may be a case that an optimal installation angle with respect to the coma aberration is changed in every wavelength. Further, there may be a case that due to manufacturing errors or arrangement errors or the like of optical components through which the light beam of the first to third wavelengths passes, the coma aberration generated in the light beam of the respective wavelengths is changed. Further, in the case where the compatible objective lens is made of plastic, in consideration of temperature characteristics of lens tilt coma aberration sensitivity, it is necessary to firstly adjust the installation angle in the case where the first wavelength corresponding to high density recording is used. Thus, the optical pickup 80 is skew-adjusted so that the initial coma aberration with respect to the first wavelength is reduced as described later with reference to FIG. 23B. With such a configuration, if the objective lens 82 in this state is used, coma aberration may be generated with respect to the second and third wavelengths. In this respect, in the case where the second and third wavelengths are used, the objective lens 82 capable of being inclined in the tilt direction allows the recording and reproducing in the optimal state even in the case where the second and third wavelengths are used.

In addition, the objective lens 82 is installed so that a light guiding optical system coincides with the optical axis, similarly to the embodiment as described with reference to FIG. 6A. That is, as shown in FIG. 23A, the objective lens 82 is installed so that an optical axis L87 of the light beam of the first wavelength which is guided by a light guiding optical system 87 approximately coincides with an optical axis L82 of the objective lens 82. Here, the light guiding optical system 87 represents optical components other than the objective lens 82 which is installed to be driven in the objective lens driving unit 51. The objective lens 82 has approximately the same characteristic as the above described first objective lens 33 with respect to the first wavelength. That is, the lens tilt coma aberration sensitivity with respect to the first wavelength under the above described condition is set to 0 to 0.3[λrms/°].

In the optical pickup 80 having such a configuration, the light beam of the wavelength corresponding to the type of the mounted optical disc among the light beams of the first to third wavelengths is emitted from light emitting units installed in the first and second light sources 31 and 32, according to the type of the mounted optical disc. Further, the optical pickup 80 displaces the objective lens 82 on the basis of a focus servo signal and a tracking servo signal which are generated by a returning light beam detected by the photodetector 86. As described above, as the objective lens 82 is displaced by the servo signal to be focused on a recording track of the optical disc 2, the optical pickup 80 performs recording or reproducing of an information signal.

Since the temperature characteristic of the lens tilt coma aberration sensitivity with respect to the first optical disc and the first wavelength of the objective lens 82 included in the optical pickup 80 is the same as that of the first objective lens 33 as described in “3. Temperature characteristic of lens tilt coma aberration sensitivity of objective lens”, detailed description thereof will be omitted.

Next, in the optical pickup 80, correction of the initial com aberration, relative angle adjustment of the optical pickup and functions and effects of the optical pickup will be described, which is approximately the same as those in the above described “4. Correction of initial coma aberration”, “5. Relative angle adjustment of optical pickup with respect to optical disc” and “6. Functions and effects of optical pickup”.

In the optical pickup 80, the correction of the initial coma aberration with respect to the first wavelength is performed by adjusting a relative inclination between the optical pickup 2 and the optical pickup 80 when forming the optical disc apparatus 1. That is, similarly to the description with reference to FIG. 7, as shown in FIG. 23B, the optical pickup 80 is skew-adjusted, to thereby restrict the initial coma aberration. At this time, since the objective lens 82 is common to the dual and triple wavelengths, the skew adjustment is performed to restrict the initial coma aberration with respect to the first wavelength corresponding to the first optical disc which is the high density recording optical disc.

The optical pickup 80 according to the present embodiment has a characteristic that the plastic objective lens 82 corresponds to the high density recording such as BD and is installed in the lens holder 52 in the state that the optical axis of the objective lens 82 coincides with the optical axis of the light guiding optical system 87. Further, the optical pickup 80 has a characteristic that the optical pickup 80 is adjusted to be inclined so that the initial coma aberration of the objective lens 82 with respect to the first wavelength is corrected in a relation to the disc installation reference surface 67a. In this way, the optical pickup 80 is configured in consideration with the temperature characteristic of the lens tilt coma aberration sensitivity of the objective lens 82. With such a configuration, the optical pickup 80 may reduce variation of the coma aberration when using the light beam of the first wavelength which is a short wavelength when there is an environment temperature change, and thus, may perform recording and reproducing in the state that the coma aberration is reduced. Thus, the optical pickup 80 employ the plastic objective lens 82 corresponding to the high density recording optical disc, to thereby enhance productivity or weight saving. In addition, the optical pickup 80 employs the configuration in consideration of variation of the lens tilt coma aberration sensitivity, to thereby realize desirable recording and reproducing characteristics even in the case where there is an environment temperature change.

Further, in the optical pickup 80, a direction of the coma aberration of the objective lens and an installation direction are the same as in “7. Direction of coma aberration of objective lens and installation direction”, except that the number of the objective lens is one. Further, a manufacturing method of the optical pickup 80 is approximately the same as in “8. Manufacturing method of optical pickup”, except that the number of the objective lens is one. In step S4, differently from an optimal angle calculation in the case where the first and second objective lenses 33 and 34 are used, an optimal angle in the case where the first and second wavelengths are used is calculated. In step S5, the optical pickup 80 is adjusted to be an optimal angle in the case where the first wavelength is used, and is installed to the optical disc apparatus 1. Further, in step S6, an optimal tilt angle in the case where the second wavelength is used is calculated to be stored in an internal memory 26.

According to such an optical pickup manufacturing method, the optical pickup 80 having effects that variation of coma aberration in temperature change in the case where the plastic lens is used as the compatible objective lens which is used for the high density recording are reduced may be manufactured.

Further, a control method of the optical pickup 80 is approximately the same as in “9. Control method of optical pickup”, except that the number of the objective lens is one. In step S14, the optical pickup 80 emits the light beam of the first wavelength with respect to the first optical disc in the state that the tilt correction mechanism is not used to perform recording and reproducing of an information signal. That is, the objective lens 82 is not inclined in the tilt direction. In step S16, the optical pickup 80 emits the light beam of the second wavelength with respect to the second optical disc using the objective lens driving unit 51 which is the tilt correction mechanism to perform recording and reproducing of the information signal. That is, as shown in FIG. 23C, the objective lens 82 is inclined in the tilt direction.

According to such an optical pickup control method, coma aberration due to an environment temperature change is reduced by means of the optical pickup 80 using the plastic lens which is the compatible objective lens which is used for high density recording, to thereby realize desirable recording and reproducing characteristics.

As described above, the optical pickup 80 according to the present embodiment employs the plastic objective lens 82, to enhance productivity and weight saving, to reduce the coma aberration due to the environment temperature change, thereby realizing desirable recording and reproducing characteristics. That is, the optical pickup 80 realizes productivity and weight saving, and also realizes desirable recording and reproducing characteristics. In addition, the optical pickup 80 realizes miniaturization by commonly using the optical system or optical components.

In the above described optical pickup 3 and optical pickup 80, the objective lens is inclined by the objective lens driving unit 51 which is the tilt correction mechanism when performing recording and reproducing of the second and third optical discs to reduce the coma aberration, but this is not limitative but used as an example. That is, the objective lens driving unit 51 which is the tilt correction mechanism generates coma aberration in the light beam focused by the objective lens by inclining the objective lens to adjust the coma aberration on the signal recording surface. In other words, the optical pickup 3 and optical pickup 80 include the objective lens driving unit 51 which is the coma aberration adjusting unit which adjusts the coma aberration of the light beam focused by the objective lens, but the coma aberration adjusting unit installed in the optical pickup is not limited thereto. That is, the invention may be applied to an optical pickup having a liquid crystal element as the coma aberration adjusting unit.

11. Still Another Example of Optical Pickup (Third Embodiment)

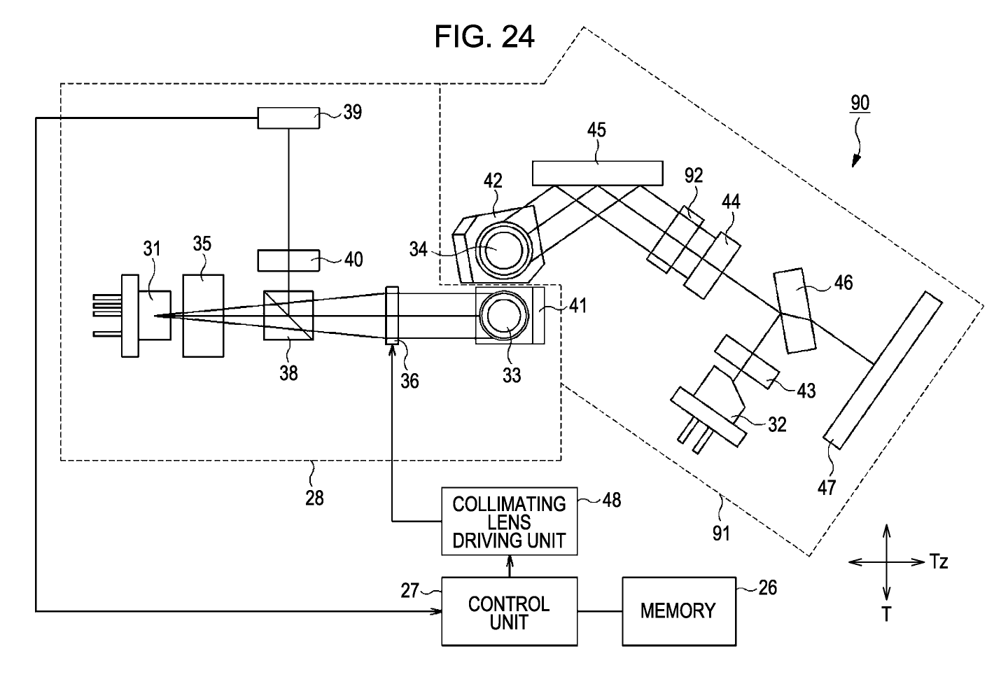

Hereinafter, an optical pickup 90 which is still another example an optical pickup according to an embodiment of the present invention and includes a liquid crystal element as a coma aberration adjusting unit will be described with reference to FIG. 24. Here, since the remaining configuration of the optical pickup 90, other than the configuration that the liquid crystal element is installed and an objective lens driving unit 51 is a so-called biaxial actuator, is the same as that of the optical pickup 3, like reference numbers are given to like elements and detailed description thereof may be omitted.

As shown in FIG. 24, the optical pickup 90 includes first and second light sources 31 and 32, and first and second objective lenses 33 and 34. Further, the optical pickup 90 includes an objective lens driving unit 51 which includes a lens holder 52, a support 53, and suspensions 54 and the like, similarly to the optical pickup 3. However, the objective lens driving unit 51 for use in the optical pickup 90 is the so-called biaxial actuator which is capable of driving the objective lenses only in a tracking direction and in a focus direction, for the convenience of description.

Further, the optical pickup 90 includes a first grating 35, a first collimating lens 36, a first raising mirror 41, a quarter wavelength plate 49, a polarized beam splitter 38, a first photodetector 39 and a multi lens 40, as a first light guiding optical system 28.

Further, the optical pickup 90 includes a second grating 43, a second collimating lens 44, a bent up mirror 45, a second raising mirror 42, a beam splitter 46 and a second photodetector 47, as a second light guiding optical system 91. Further, the optical pickup 90 includes a liquid crystal element 92 installed between the second collimating lens 44 and the bent up mirror 45, as the second light guiding optical system 91. The liquid crystal 92 includes a pair of electrodes which has an electrode pattern capable of generating coma aberration, and liquid crystal molecules which are interposed between the pair of electrodes through alignment layers, etc. Such a liquid crystal element 92 may generate coma aberration of a predetermined intensity in a light beam passing through the liquid crystal element 92 as a predetermined electric current is applied to the liquid crystal element 92, to thereby adjust coma aberration of an optical disc. In other words, the liquid crystal element 92 generates the coma aberration for offsetting coma aberration by relatively skew-adjusting the optical pickup itself as shown in FIG. 7, so as to reduce the coma aberration. Coma aberration generated due to manufacturing errors or arrangement errors of the second light guiding optical system 91 or the second objective lens 34 may be included in the offset coma aberration.

The optical pickup 90 including the liquid crystal element 92 provides predetermined coma aberration to light beams entering into the second and third optical discs, unlike the optical pickup 3 in which the second objective lens 34 is inclined in the tilt direction as shown in FIG. 8. The amount of the coma aberration is the same as the amount of the coma aberration generated when the second objective lens 34 is inclined by the appropriated tilt angle θA in the above described optical pickup 3. Accordingly, the optical pickup 90 may perform recording and/or reproducing in an optimal state using the liquid crystal element 92 when recording and/or reproducing the second and third optical discs.

The optical pickup 90 having the above described configuration emits a light beam having a wavelength corresponding to the type of the optical disc among light beams having first to third wavelengths from light emitting units installed in the first and second light sources 31 and 32, according to the type of the mounted optical disc. Further, the optical pickup 90 drives the first and second objective lenses 33 and 34 to be displaced on the basis of a focus servo signal and a tracking servo signal generated by a returning light beam detected by the first and second photodetectors 39 and 47. Accordingly, the optical pickup 90 performs recording or reproducing of an information signal with respect to the optical disc 2 as each objective lens is driven to be displaced by the servo signal as described above.

In such an optical pickup 90, since temperature characteristics of the lens tilt coma aberration sensitivity, correction of the coma aberration amount, relative angle adjustment of the optical pickup and functions and effects of the optical pickup are the same as in the above described “3. Temperature characteristic of lens tilt coma aberration sensitivity of objective lens” to “6. Functions and effects of optical pickup”, detailed description thereof will be omitted. Further, the optical pickup 90 has a characteristic that the optical pickup 90 corresponds to high density recording such as BD and the first objective lens 33 made of plastic is held by the lens holder 52 in the state that the optical axes of the first objective lens 33 and the first light guiding optical system 28 coincide with each other. Further, the optical pickup 90 has a characteristic that the optical pickup 90 is adjusted to be inclined to correct the initial coma aberration of the first objective lens 33 in the relation to the disc installation reference surface 67a. In this way, the optical pickup 90 is configured in consideration of temperature characteristics of the lens tilt coma aberration sensitivity of the first objective lens 33. The optical pickup 90 reduces variation of coma aberration even when there is an environment temperature change with such a configuration, that is, may perform recording and reproducing in the state that the coma aberration is reduced. Thus, the optical pickup 90 employs the plastic first objective lens 33 to enhance productivity and weight saving, and employs the configuration in consideration of variation of the lens tilt coma aberration sensitivity to realize desirable recording and reproducing even when there is an environment temperature change.

In addition, the optical pickup 90 does not use the liquid crystal element 92 which is a coma aberration generating unit even though the environment temperature is changed when performing reproducing the first optical disc, and drives the liquid crystal element 92 to generate coma aberration in order to obtain an optimal reproducing environment in the second and third optical disc reproducing. Accordingly, the optical pickup 90 may perform recording and reproducing in the state that the coma aberration is reduced with respect to the second and third optical discs. Further, in the optical pickup 90, the objective lens driving unit 51 may be configured as a bi-axial actuator, not as a tri-axial actuator by installation of the liquid crystal element 92, and thus, simplification and miniaturization of the apparatus may be realized.

In addition, in the optical pickup 90, a direction of the coma aberration of the objective lens and an installation direction are the same as in “7. Direction of coma aberration of objective lens and installation direction”. Further, a manufacturing method of the optical pickup 90 is approximately the same as in “8. Manufacturing method of optical pickup”, except that the liquid crystal element is installed instead of the tilt correction mechanism. In step S6, differently from an optimal tilt angle calculation in the case where the second objective lens 34 is used, the amount of the coma aberration generated in the liquid crystal element 92 in the case where the second objective lens 34 is used is calculated. The amount of the coma aberration is the same as the amount of the coma aberration generated by the optimal tilt angle θA shown in FIG. 8. Further, in step S6, the calculated coma aberration amount is stored in a storing unit such as a memory 26 or the like. According to the optical pickup manufacturing method, in the case where the plastic objective lens for the above described high density recording optical disc is used, the optical pickup 90 having effects that variation of the coma aberration in temperature change is reduced can be manufactured. Further, the manufacturing method of the optical pickup 90 is approximately the same as the configuration described in “9. Control method of optical pickup”, except that the liquid crystal element is installed in place of the tilt correction mechanism. In step S14, the optical pickup 90 emits the light beam of the first wavelength with respect to the first optical disc in the state that the liquid crystal element 92 which is the coma aberration generating unit is not used to perform the recording and reproducing of the information signal. In addition, in step S16, the optical pickup 90 emits the light beam of the second wavelength with respect to the second optical disc in the state that the coma aberration is reduced using the liquid crystal element 90 which is the coma aberration generating unit to perform the recording and reproducing of the information signal. According to the optical pickup control method, the coma aberration due to an environment temperature change by means of the optical pickup 90 which uses the plastic lens which is the objective lens for the high density recording is reduced to realize preferable recording and reproducing characteristics.

As described above, the optical pickup 90 according to the present embodiment employs the plastic objective lens to enhance productivity or weight saving, and to reduce the coma aberration due to the environment temperature change to realize the preferable recording and reproducing characteristics. That is, the optical pickup 90 realizes productivity or weight saving and realizes preferable recording and reproducing characteristics. Further, the objective lens driving unit 51 in the optical pickup 90 may be configured as a bi-axial actuator, to thereby realize simplicity and miniaturization of the configuration, compared with a tri-actuator.

Hereinbefore, the optical pickup 90 provided with the liquid crystal element 92 which is the coma aberration generating unit according to the modified example with respect to the optical pickup 3 is described, but a liquid crystal element as a modified example of the optical pickup 80 may be installed. In such a case, for example, the above described liquid crystal element 92 is installed between the collimating lens 83 and the raising mirror 41, and thus, the objective lens driving unit 51 is provided as a bi-axial actuator. Such an optical pickup has both the effects of the optical pickup 80 and the optical pickup 90.

12. Effects of Optical Disc Apparatus

Further, the optical disc apparatus 1 according to the embodiments of the invention includes the optical pickup which emits the light beam with respect to the optical disc 2 which is driven to rotate to perform recording and/or reproducing of the information signal, and uses the above described optical pickup 3 or the like as the optical pickup. Accordingly, the optical disc apparatus 1 realizes productivity or weight saving and also realizes reduction in coma aberration in temperature change, thereby realizing preferable recording and reproducing characteristics.

The present application contains subject matter related to that disclosed in Japanese Priority Patent Application JP 2009-108248 filed in the Japan Patent Office on Apr. 27, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An optical pickup comprising:
a first and a second objective lenses which are configured to focus light beams having different wavelengths onto a first and a second optical discs having protection layers of different thicknesses, respectively;
a coma aberration generating unit which is configured to generate coma aberration in the light beams passing through the first and/or second objective lenses;
a collimating lens which is installed on a light path between a light source for emitting the light beam and the first objective lens and is configured to convert a divergent angle of the light beam passing through the collimating lens; and
a collimating lens driving unit which is configured to move the collimating lens in an optical axis direction and change an angle of the light beam entering into the first objective lens to correct spherical aberration,
wherein the protection layer thickness of the first optical disc corresponding to the first objective lens is smaller than that of the second optical disc corresponding to the second objective lens,
wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens,
wherein the first objective lens is made of plastic and is installed so that an optical axis of the light beam, which is guided by a light guiding optical system which guides the light beam to the first objective lens, approximately coincides with an optical axis of the first objective lens;
wherein the optical pickup is inclined relative to the optical disc at an angle at which initial coma aberration with respect to the first optical disc due to the first objective lens is optimally corrected; and
wherein the coma aberration generating unit is not used when reproducing the first optical disc and the coma aberration generating unit is used for obtaining optimal reproducing environment when reproducing the second optical disc.

2. The optical pickup according to claim 1, wherein the coma aberration generating unit has a lens holder which holds the first and second objective lenses, the coma aberration generating unit being a tilt correction mechanism which drives and inclines the lens holder in a tilt direction, and wherein the tilt correction mechanism is not used when reproducing the first optical disc and is used to obtain the optimal reproducing environment when reproducing the second optical disc to incline the lens holder.

3. The optical pickup according to claim 1, wherein the coma aberration generating unit is a liquid crystal element.

4. The optical pickup according to claim 2 or 3, wherein the first and second objective lenses are arranged toward a radial direction of the optical disc so that the coma aberration of the first and second objective lenses has the same direction.

5. An optical disc apparatus including an optical pickup which emits a light beam onto an optical disc which is driven to rotate, to perform recording and/or reproducing of an information signal,
the optical pickup comprising:
a first and a second objective lenses which are configured to focus light beams having different wavelengths onto a first and a second optical discs having protection layers of different thicknesses, respectively;
a coma aberration generating unit which is configured to generate coma aberration in the lights beam passing through the first and/or second objective lenses;
a collimating lens which is installed on a light path between a light source for emitting the light beam and the first and second objective lenses and is configured to convert a divergent angle of the light beams passing through the collimating lens; and
a collimating lens driving unit which is configured to move the collimating lens in an optical axis direction and change angles of the light beams entering into the objective lenses to correct spherical aberration,
wherein the protection layer thickness of the first optical disc corresponding to the first objective lens is smaller than that of the second optical disc corresponding to the second objective lens,
wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens,
wherein the first objective lens is made of plastic and is installed so that an optical axis of the light beam which is guided by a light guiding optical system which guides the light beam to the first objective lens approximately coincides with an optical axis of the first objective lens;
wherein at least one of the optical pickup and a disc mounting unit on which the optical disc is to be mounted is inclined so that the optical pickup and the optical disc mounted on the disc mounting unit are inclined relative to each other at an angle at which initial coma aberration with respect to the first optical disc due to the first objective lens is optimally corrected; and
wherein the coma aberration generating unit is not used when reproducing the first optical disc and the coma aberration generating unit is used for obtaining optimal reproducing environment when reproducing the second optical disc.

6. A method of manufacturing an optical pickup,
the optical pickup including:
a first and a second objective lenses which are configured to focus light beams having different wavelengths onto a first and a second optical discs having protection layers of different thicknesses, respectively;
a coma aberration generating unit which is configured to generate coma aberration in the light beams passing through the first and/or second objective lenses;
a collimating lens which is installed on a light path between a light source for emitting the light beam and the first objective lens, and is configured to convert a divergent angle of the light beam passing through the collimating lens; and
a collimating lens driving unit which is configured to move the collimating lens in an optical axis direction and change angles of the light beams entering into the objective lenses to correct spherical aberration,
wherein the protection layer thickness of the first optical disc corresponding to the first objective lens is smaller than that of the second optical disc corresponding to the second objective lens, and
wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens,
in manufacturing the optical pickup having the first objective lens which is made of plastic, the method comprising the steps of:
installing a light guiding optical system, which guides the light beam to the first objective lens, to a base member;
holding the first objective lens to a lens holder so that an optical axis of the light beam, which is guided by the light guiding optical system to the first objective lens approximately coincides with an optical axis of the first objective lens;
adjusting the optical pickup so that the optical pickup is inclined relative to the optical disc at an angle at which initial coma aberration with respect to the first optical disc due to the first objective lens is optimally corrected; and
calculating a coma aberration correction amount in which initial coma aberration with respect to the second optical disc due to the second objective lens is optimally corrected using the coma aberration generating unit and storing the calculated coma aberration correction amount in a storage unit.

7. A method of controlling an optical pickup,
the optical pickup including:
a first and a second objective lenses which are configured to focus light beams having different wavelengths onto a first and a second optical discs having protection layers of different thicknesses, respectively;
a coma aberration generating unit which is configured to generate coma aberration in the light beams passing through the first and/or second objective lenses;
a collimating lens which is installed on a light path between a light source for emitting the light beam and the first objective lens, and is configured to convert a divergent angle of the light beam passing through the collimating lens; and
a collimating lens driving unit which is configured to move the collimating lens in an optical axis direction and change angles of the light beams entering into the objective lenses to correct spherical aberration,
wherein the protection layer thickness of the first optical disc corresponding to the first objective lens is smaller than that of the second optical disc corresponding to the second objective lens,
wherein the first objective lens satisfies, under a condition that environmental temperature is 0° C. to 70° C., the protection layer thickness of the corresponding first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the first objective lens in a state that the generated spherical aberration is corrected by moving the collimating lens, and
wherein the first objective lens is made of plastic and is installed so that an optical axis of the light beam, which is guided by a light guiding optical system which guides the light beam to the first and second objective lenses, approximately coincides with an optical axis of the first objective lens,
in controlling the optical pickup so that the optical pickup is inclined relative to the optical disc at an angle at which initial coma aberration with respect to the first optical disc due to the first objective lens is optimally corrected, the method comprising the steps of:
discerning the type of the mounted optical disc;
performing, when it is the first optical disc which is discerned by the discerning step, reproduction of an information signal with respect to the first optical disc without using the coma aberration generating unit; and
performing, when it is the second optical disc which is discerned by the discerning step, reproduction of an information signal with respect to the second optical disc using the coma aberration generating unit.

8. An optical pickup comprising:
a single objective lens which is configured to focus light beams having different wavelengths onto a first and a second optical discs having protection layers of different thicknesses, respectively;
a coma aberration generating unit which is configured to generate coma aberration in the light beams passing through the objective lens;
a collimating lens which is installed on a light path between a light source for emitting the light beam and the objective lens, and is configured to convert a divergent angle of the light beam passing through the collimating lens; and
a collimating lens driving unit which is configured to move the collimating lens in an optical axis direction and change an angle of the light beam entering into the objective lens to correct spherical aberration,
wherein the protection layer thickness of the first optical disc is smaller than that of the second optical disc,
wherein the objective lens satisfies, under a condition that environmental temperature is 0° C. to 70° C., the protection layer thickness of the corresponding first optical disc is 70 μm to 105 μm, and a wavelength λ1 of the light beam corresponding to the first optical disc is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens,
wherein the objective lens is made of plastic, and is installed so that an optical axis of the light beam, which is guided by a light guiding optical system which guides the light beam to the objective lens, approximately coincides with an optical axis of the objective lens;
wherein the optical pickup is inclined relative to the optical disc at an angle at which initial coma aberration with respect to the first optical disc due to the objective lens is optimally corrected; and
wherein the coma aberration generating unit is not used when reproducing the first optical disc and the coma aberration generating unit is used for obtaining optimal reproducing environment when reproducing the second optical disc.

9. The optical pickup according to claim 8, wherein the coma aberration generating unit has a lens holder which holds the objective lens, the coma aberration generating unit being a tilt correction mechanism which drives and inclines the lens holder in a tilt direction, and wherein the tilt correction mechanism is not used when reproducing the first optical disc and the tilt correction mechanism is used to obtain the optimal reproducing environment when reproducing the second optical disc to incline the lens holder.

10. The optical pickup according to claim 8, wherein the coma aberration generating unit is a liquid crystal element.

11. An optical disc apparatus including an optical pickup which emits a light beam onto an optical disc which is driven to rotate, to perform recording and/or reproducing of an information signal,
the optical pickup comprising:
a single objective lens which is configured to focus light beams having different wavelengths onto a first and a second optical discs having protection layers of different thicknesses, respectively;
a coma aberration generating unit which is configured to generate coma aberration in the lights beam passing through the objective lens;
a collimating lens which is installed on a light path between a light source for emitting the light beam and the objective lens, and is configured to convert a divergent angle of the light beam passing through the collimating lens; and
a collimating lens driving unit which is configured to move the collimating lens in an optical axis direction and change an angle of the light beam entering into the objective lens to correct spherical aberration,
wherein the protection layer thickness of the first optical disc corresponding to the first objective lens is smaller than that of the second optical disc corresponding to the second objective lens,
wherein the objective lens satisfies, under a condition that environmental temperature is 0° C. to 70° C., the protection layer thickness of the first optical disc corresponding to the first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens,
wherein the objective lens is made of plastic and is installed so that an optical axis of the light beam, which is guided by a light guiding optical system which guides the light beam to the objective lens, approximately coincides with an optical axis of the objective lens;
wherein at least one of the optical pickup and a disc mounting unit on which the optical disc is to be mounted is inclined so that the optical pickup and the optical disc mounted on the disc mounting unit are inclined relative to each other at an angle at which initial coma aberration with respect to the first optical disc due to the objective lens is optimally corrected; and
wherein the coma aberration generating unit is not used when reproducing the first optical disc and the coma aberration generating unit is used for obtaining optimal reproducing environment when reproducing the second optical disc.

12. A method of manufacturing an optical pickup,
the optical pickup including:
a single objective lens which is configured to focus light beams having different wavelengths onto a first and a second optical discs having protection layers of different thicknesses, respectively;
a coma aberration generating unit which is configured to generate coma aberration in the light beam passing through the objective lens;
a collimating lens which is installed on a light path between a light source for emitting the light beam and the objective lens and is configured to convert a divergent angle of the light beam passing through the collimating lens; and
a collimating lens driving unit which is configured to move the collimating lens in an optical axis direction and change an angle of the light beam entering into the objective lens to correct spherical aberration,
wherein the protection layer thickness of the first optical disc is smaller than that of the second optical disc, and
wherein the objective lens satisfies, under a condition that environmental temperature is 0° C. to 70° C., the protection layer thickness of the corresponding first optical disc is 70 μm to 105 μm, and a wavelength λ1 of the light beam corresponding to the first optical disc is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens,
in manufacturing the optical pickup having the objective lens which is made of plastic, the method comprising the steps of:
installing a light guiding optical system, which guides the light beam to the objective lens, to a base member;
holding the objective lens to a lens holder so that an optical axis of the light beam which is guided by the light guiding optical system to the objective lens approximately coincides with an optical axis of the objective lens;
adjusting the optical pickup so that the optical pickup is inclined relative to the optical disc at an angle at which initial coma aberration with respect to the first optical disc due to the objective lens is optimally corrected; and
calculating a coma aberration correction amount in which initial coma aberration with respect to the second optical disc due to the objective lens is optimally corrected using the coma aberration generating unit and storing the calculated coma aberration correction amount in a storage unit.

13. A method of controlling an optical pickup,
the optical pickup including:
a single objective lens which is configured to focus light beams having different wavelengths onto a first and a second optical discs having protection layers of different thicknesses, respectively;
a coma aberration generating unit which is configured to generate coma aberration in the light beam passing through the objective lens;
a collimating lens which is installed on a light path between a light source for emitting the light beam and the objective lens, and is configured to convert a divergent angle of the light beam passing through the collimating lens; and
a collimating lens driving unit which is configured to move the collimating lens in an optical axis direction and change an angle of the light beams entering into the objective lens to correct spherical aberration,
wherein the protection layer thickness of the first optical disc is smaller than that of the second optical disc,
wherein the objective lens satisfies, under a condition that environmental temperature is 0° C. to 70° C., the protection layer thickness of the first optical disc corresponding to the first optical disc is 70 μm to 105 μm, and a wavelength λ1 of the corresponding light beam is 398 nm to 414 nm, a lens tilt coma aberration sensitivity of 0 to 0.3[λrms/°] which is a ratio of the coma aberration generated in the light beam by inclining the objective lens in a state that the generated spherical aberration is corrected by moving the collimating lens, and
wherein the objective lens is made of plastic and is installed so that an optical axis of the light beam, which is guided by a light guiding optical system which guides the light beam to the objective lens, approximately coincides with an optical axis of the objective lens,
in controlling the optical pickup so that the optical pickup is inclined relative to the optical disc at an angle at which initial coma aberration with respect to the first optical disc due to the objective lens is optimally corrected, the method comprising the steps of:
discerning the type of the mounted optical disc;
performing, when it is the first optical disc which is discerned by the discerning step, reproduction of an information signal with respect to the first optical disc without using the coma aberration generating unit; and
performing, when it is the second optical disc which is discerned by the discerning step, reproduction of an information signal with respect to the second optical disc using the coma aberration generating unit.
